(19) United States
(12) Patent Application Publication
(10) Pub. No.: US 2014/0179055 A1
(43) Pub. Date: Jun. 26, 2014

(54) METHOD FOR PRODUCING PHOTOELECTRIC CONVERSION ELEMENT AND METHOD FOR PRODUCING IMAGING DEVICE

(71) Applicant: FUJIFILM CORPORATION, TOKYO (JP)

(72) Inventor: Hideyuki SUZUKI, Ashigara-kami-gun (JP)

(73) Assignee: FUJIFILM CORPORATION, TOKYO (JP)

(21) Appl. No.: 14/194,419

(22) Filed: Feb. 28, 2014

Related U.S. Application Data
(63) Continuation of application No. PCT/JP2012/069680, filed on Aug. 2, 2012.

(30) Foreign Application Priority Data
Sep. 1, 2011 (JP) 2011-190588

(51) Int. Cl. H01L 51/56

(52) U.S. Cl. CPC H01L 51/56
USPC 438/93

(57) ABSTRACT

The method produces a photoelectric conversion element comprising a lower electrode, an electron blocking layer, a photoelectric conversion layer, an upper electrode, and a sealing layer which are laminated on one another in this order. The method includes a step of forming a transparent conductive oxide into a film at a deposition rate of 0.5 Å/s or higher by a sputtering method to form the upper electrode having a stress of −50 MPa to −500 MPa on the photoelectric conversion layer.

### CROSS REFERENCE TO RELATED APPLICATIONS

This application is a continuation application of International Application PCT/JP2012/069680 filed on Aug. 2, 2012, which claims priority under 35 U.S.C. 119(a) to Application No. 2011-190588 filed in Japan on Sep. 1, 2011, all of which are hereby expressly incorporated by reference into the present application.

### BACKGROUND OF THE INVENTION

The present invention relates to a method for producing a photoelectric conversion element having a photoelectric conversion layer that contains an organic substance and to a method for producing an imaging device. Particularly, the present invention relates to a method for producing a photoelectric conversion element which has a high SN ratio showing a low level of dark currents and the like and stays stable over a long period of time, and to a method for producing an imaging device using the photoelectric conversion element.

A photoelectric conversion element having a pair of electrodes and a photoelectric conversion layer which uses an organic compound disposed between the pair of electrodes is known. Currently, photoelectric conversion elements using organic compounds and imaging devices are under development (for example, see JP 2007-88440 A, JP 2010-103457 A, and JP 2011-71481 A).

For the purpose of realizing a photoelectric conversion element having a low level of dark currents, JP 2007-88440 A discloses a photoelectric conversion element in which a transparent electrode is used as an upper electrode of an organic photoelectric conversion element, and the thickness of the transparent electrode is set to be less than one fifth of the thickness of a photoelectric conversion film.

Moreover, for the purpose of realizing a photoelectric conversion element having a high S/N ratio and a high response speed, JP 2010-103457 A discloses a photoelectric conversion element having a structure in which a bulk heterostructure is used for a photoelectric conversion layer, and a transparent electrode is formed in the form of a film which comes into direct contact with the top of the photoelectric conversion layer.

Furthermore, JP 2011-71481 A discloses a solid-state imaging device having a sealing layer for preventing intrusion of factors that deteriorate photoelectric conversion materials.

### SUMMARY OF THE INVENTION

However, in order to prepare an imaging device by using the photoelectric conversion element disclosed in JP 2010-103457 A and to use this device, the device needs to have a high S/N ratio and a high response speed over a long period of time.

Moreover, JP 2011-71481 A discloses neither the test results nor the description regarding long term stability. Therefore, there is a demand for an organic photoelectric conversion element which has a high SN ratio and stays stable over a long period of time.

The present invention aims to resolve the problems in the conventional technique described above and to provide a method for producing a photoelectric conversion element which has a high SN ratio showing a low level of dark current and the like and stays stable over a long period of time, and a method for producing an imaging device.

In order to attain the above-described object, the present invention provides a method for producing a photoelectric conversion element comprising a lower electrode, an electron blocking layer, a photoelectric conversion layer, an upper electrode, and a sealing layer which are laminated on one another in this order, the method having the steps of: preparing a substrate on which the lower electrode, the electron blocking layer and the photoelectric conversion layer are formed in this order; and forming a transparent conductive oxide into a film at a deposition rate of 0.5 Å/s or higher by a sputtering method to form the upper electrode having a stress of −50 MPa to −500 MPa on the photoelectric conversion layer.

Preferably, the photoelectric conversion layer has a bulk heterostructure in which an n-type organic semiconductor material is mixed with a p-type organic semiconductor material. Preferably, the n-type organic semiconductor material is a fullerene or a fullerene derivative.

Preferably, the upper electrode has a thickness of 5 nm to 20 nm. Preferably, the upper electrode is formed at a deposition rate of 10 Å/s or lower.

In addition, the p-type organic semiconductor material preferably contains a compound represented by General formula (1).

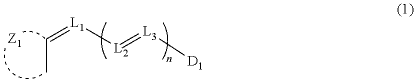

In General formula (1), Z₁ is a ring which contains at least two carbon atoms, and represents a 5-membered ring, a 6-membered ring, or a condensed ring which contains at least one of 5-membered ring and 6-membered ring; each of L₁, L₂, and L₃ independently represents unsubstituted methine groups or substituted methine groups; D₁ represents an atomic group; and n represents an integer of 0 or greater.

Moreover, the present invention provides a method for producing an imaging device having a photoelectric conversion element, the method having a step of producing the photoelectric conversion element by the method for producing a photoelectric conversion element of the present invention.

According to the present invention, it is possible to obtain a photoelectric conversion element and an imaging device which have a high SN ratio showing a low level of dark current and the like and stay stable over a long period of time.

### BRIEF DESCRIPTION OF THE DRAWINGS

FIG. 1 is a schematic cross-sectional view showing a photoelectric conversion element according to an embodiment of the present invention.

FIGS. 2A and 2B are schematic cross-sectional views for respectively illustrating stress acting on a thin film formed on a substrate.

FIG. 3 is a schematic view showing an apparatus for measuring a degree of warpage of a substrate on which a thin film has been formed.

FIG. 4 is a schematic cross-sectional view showing an imaging device according to an embodiment of the present invention.

FIGS. 5A to 5C are schematic cross-sectional views showing the method for producing the imaging device according to an embodiment of the present invention in order of steps.

FIGS. 6A and 6B are schematic cross-sectional views showing the method for producing the imaging device according to an embodiment of the present invention in order of steps, after the step shown in FIG. 5C.

### DETAILED DESCRIPTION OF THE INVENTION

Hereinafter, based on preferable embodiments shown in the attached drawings, the method for producing a photoelectric conversion element of the present invention and the method for producing an imaging device of the present invention will be described in detail.

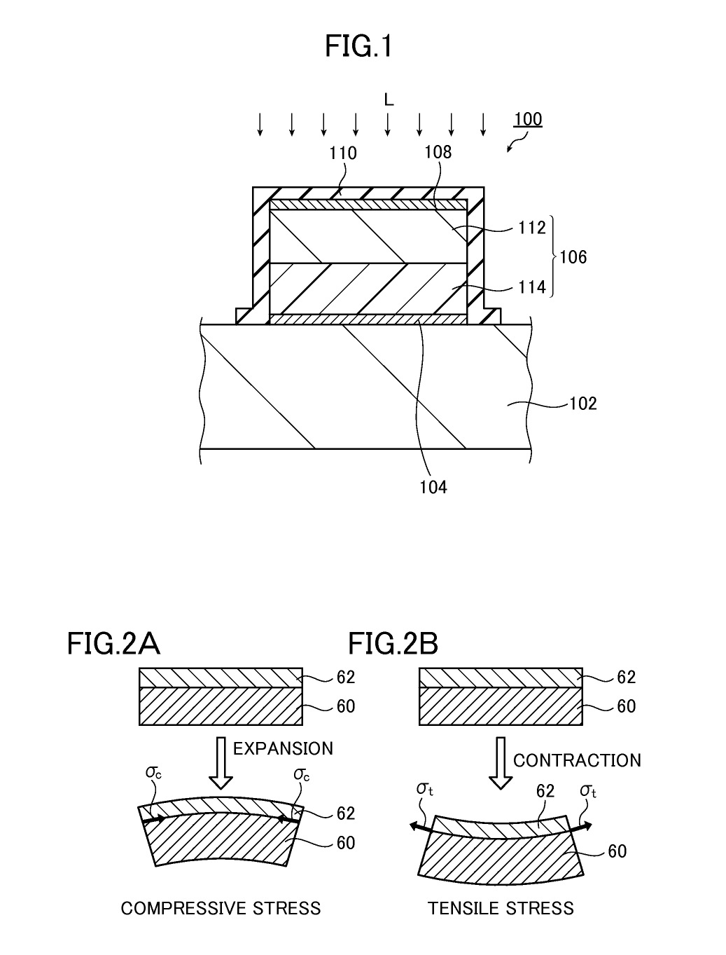

In a photoelectric conversion element 100 shown in FIG. 1, a lower electrode 104 is formed on a substrate 102, and a photoelectric conversion portion 106 is formed on the lower electrode 104. On the photoelectric conversion portion 106, an upper electrode 108 is formed. The photoelectric conversion portion 106 is disposed between the lower electrode 104 and the upper electrode 108. The photoelectric conversion portion 106 has a photoelectric conversion layer 112 containing an organic substance and an electron blocking layer 114, and the electron blocking layer 114 is formed on the lower electrode 104.

A sealing layer 110 is provided so as to cover the upper electrode 108, thereby sealing the lower electrode 104, the upper electrode 108, and the photoelectric conversion portion 106.

The substrate 102 is constituted with, for example, a silicon substrate or a glass substrate.

The lower electrode 104 is an electrode for collecting holes from electric charges generated by the photoelectric conversion portion 106. Examples of the material of the lower electrode 104 include metals, metal oxides, metal nitrides, metal borides, organic conductive compounds, mixtures of these, and the like. Specific examples thereof include conductive metal oxides such as tin oxide, zinc oxide, indium oxide, indium tin oxide (ITO), indium zinc oxide (IZO), indium tungsten oxide (IWO), and titanium oxide; metal nitrides such as titanium nitride (TiN); metals such as gold (Au), platinum (Pt), silver (Ag), chromium (Cr), nickel (Ni), and aluminum (Al); mixtures or laminates consisting of these metals and conductive metal oxides; organic conductive compounds such as polyaniline, polythiophene, and polypyrrole; laminates consisting of these organic conductive compounds and ITO; and the like. As a material of the lower electrode 104, any of titanium nitride, molybdenum nitride, tantalum nitride, and tungsten nitride is particularly preferable.

The photoelectric conversion layer 112 of the photoelectric conversion portion 106 is a layer constituted with a photoelectric conversion material which receives light and generates electric charges according to the amount of the light. As the photoelectric conversion material, organic compounds can be used. For example, the photoelectric conversion layer 112 is preferably a layer containing a p-type organic semiconductor material or an n-type organic semiconductor material. The photoelectric conversion layer is more preferably a bulk heterolayer as a mixture of an organic p-type compound and an organic n-type compound. The photoelectric conversion layer is even more preferably a bulk heterolayer as a mixture of an organic p-type compound and a fullerene or a fullerene derivative. If the bulk heterolayer is used as the photoelectric conversion layer 112, it is possible to improve photoelectric conversion efficiency by making up for a defect such as a short carrier diffusion length in an organic layer. If the bulk heterolayer is prepared at an optimal mixing ratio, electron mobility and hole mobility in the photoelectric conversion layer 112 can be improved, whereby an optical response speed of the photoelectric conversion element can be sufficiently increased. A proportion of a fullerene or a fullerene derivative in the bulk heterolayer is preferably 40% to 85% (volumetric proportion). The bulk heterolayer (bulk heterojunction structure) is described in detail in JP 2005-303266 A.

The thickness of the photoelectric conversion layer 112 is preferably from 10 nm to 1,000 nm, more preferably from 50 nm to 800 nm, and particularly preferably from 100 nm to 500 nm. If the thickness of the photoelectric conversion layer 112 is 10 nm or more, a preferable effect of suppressing dark currents is obtained, and if the thickness of the photoelectric conversion layer 112 is 1,000 nm or less, preferable photoelectric conversion efficiency is obtained.

It is preferable for the layer, which constitutes the photoelectric conversion layer 112 and contains the aforementioned organic compounds, to be formed by a vacuum deposition method. It is preferable for all steps at the time of deposition to be performed in a vacuum. Basically, the compounds are prevented from coming into direct contact with oxygen or moisture in the outside air. A method of controlling the deposition rate by means of PT or PID control using a film thickness monitor such as a quarts oscillator or an interferometer is preferably used. When two or more kinds of compounds are simultaneously deposited, a co-deposition method, a flash deposition method, and the like can be preferably used.

The electron blocking layer 114 is a layer for inhibiting electrons from being injected into the photoelectric conversion portion 106 from the lower electrode 104. The electron blocking layer 114 contains either or both of an organic material and an inorganic material.

The electron blocking layer 114 is a layer for preventing electrons from being injected into the photoelectric conversion portion 106 from the lower electrode 104, and is constituted with a single layer or plural layers. The electron blocking layer 114 may be constituted with a film formed of a single organic material or with a film as a mixture of plural different kinds of organic materials. It is preferable for the electron blocking layer 114 to be constituted with a material which forms a high electron injection barrier against electrons from the adjacent lower electrode 104 and has a high degree of hole transport properties. It is preferable that by the electron injection barrier, electron affinity of the electron blocking layer 114 becomes smaller than the work function of the adjacent electrode by 1 eV or more, more preferably by 1.3 eV or more, and particularly preferably by 1.5 eV or more.

It is preferable for the electron blocking layer 114 to have a thickness of 20 nm or more, more preferably 40 nm or more, and particularly preferably 60 nm or more, so as to sufficiently inhibit the contact between the lower electrode 104 and the photoelectric conversion layer 112 and to avoid the influence exerted by defectiveness or dust present on the surface of the lower electrode 104.

If the electron blocking layer 114 is too thick, this leads to a problem that voltage which needs to be supplied for applying an appropriate field intensity to the photoelectric conversion layer 112 increases, and a problem that a process of transporting carriers in the electron blocking layer 114 negatively affects the performance of the photoelectric conversion element. The total thickness of the electron blocking layer 114 is preferably 300 nm or less, more preferably 200 nm or less, and even more preferably 100 nm or less.

The upper electrode 108 is an electrode for collecting electrons from electric charges generated by the photoelectric conversion portion 106. For the upper electrode 108, in order to cause light to enter the photoelectric conversion portion 106, conductive materials (for example, ITO) having sufficient transparency with respect to the light of a wavelength to which the photoelectric conversion portion 106 has sensitivity are used. The upper electrode 108 is a transparent conductive film. By applying bias voltage between the upper electrode 108 and the lower electrode 104, of electric charges generated by the photoelectric conversion portion 106, holes can be moved to the lower electrode 104, and electrons can be moved to the upper electrode 108.

For the upper electrode 108, in order to increase an absolute amount of light entering the photoelectric conversion layer and to increase external quantum efficiency, transparent conductive oxides are used.

As a material of the upper electrode 108, any of materials including ITO, IZO, SnO₂, antimony-doped tin oxide (ATO), ZnO, Al-doped zinc oxide (AZO), gallium-doped zinc oxide (GZO), TiO₂, and fluorine-doped tin oxide (FTC) is preferable.

The optical transmittance of the upper electrode 108 is preferably 60% or higher, more preferably 80% or higher, even more preferably 90% or higher, and still more preferably 95% or higher, at visible wavelength range.

Moreover, it is preferable for the upper electrode 108 to have a thickness of 5 nm to 20 nm. If the upper electrode 108 has a film thickness of 5 nm or more, the electrode can sufficiently cover the under layer, and uniform performance is obtained. On the other hand, if the upper electrode 108 has a film thickness of 20 nm or more, a short circuit is locally caused between the upper electrode 108 and the lower electrode 104, whereby a level of dark currents increases in some cases. By setting the film thickness of the upper electrode 108 to 20 nm or less, it is possible to prevent the occurrence of local short circuit.

Various methods are used for forming the upper electrode 108 in the form of a film depending on the type of the material, but it is desirable to form the layer by a sputtering method.

When the upper electrode 108 is formed in the form of a film by a sputtering method as described above, it is preferable to form the upper electrode 108 at a deposition rate of 0.5 Å/s or higher. If the upper electrode 108 is formed at a deposition rate of 0.5 Å/s or higher, it is possible to inhibit oxygen gas, which is a factor deteriorating the photoelectric conversion material, from being incorporated into the photoelectric conversion layer 112 during the formation of the film.

Moreover, it was found that when the deposition rate for forming the upper electrode 108 is set to 0.5 Å/s or higher, in order to realize a photoelectric conversion element which shows a sufficiently low level of dark currents and stays stable over a long period of time, the stress of the upper electrode 108 needs to be controlled. It was found that the stress of the upper electrode 108 is involved with the longer term stability of the photoelectric conversion element and dark currents. It was found that if the deposition rate for forming the upper electrode 108 is 0.5 Å/s or higher, and a compressive stress of the upper electrode 108 is small, a degree of adhesiveness between the photoelectric conversion layer 112 and the upper electrode 108 decreases, whereby the upper electrode 108 is peeled from the photoelectric conversion layer 112 after a long period of time.

The stress of the upper electrode 108 is preferably −50 MPa or less. The compressive stress is indicated by a minus sign, and a stress of −50 MPa or less means that the compressive stress is 50 MPa or higher.

If the stress of the upper electrode 108 is controlled to be −50 MPa or less, sufficient adhesiveness is obtained in the interface between the photoelectric conversion layer 112 and the upper electrode 108, and the upper electrode 108 is not peeled from the photoelectric conversion layer 112 over a long period of time.

If the deposition rate for forming the upper electrode 108 is 0.5 Å/s or higher, and the compressive stress of the upper electrode 108 is high, a level of dark currents of the photoelectric conversion element increases. Although the reason has not been completely clarified, the following model is considered to be the reason. That is, if the compressive stress of the upper electrode 108 is high, when the upper electrode 108 is formed in the form of a film on the photoelectric conversion layer 112, the photoelectric conversion layer 112 is deformed and becomes convex shape due to the compressive stress of the upper electrode 108. When the photoelectric conversion layer 112 is deformed and becomes convex shape, fine cracks are formed on the surface thereof, and the transparent conductive oxide constituting the upper electrode 108 intrudes into those cracks. Presumably, to the site of the cracks into which the transparent conductive oxide has intruded, strong field intensity may be locally applied, and electric charges may be injected into the photoelectric conversion layer 112 from those cracks, whereby a level of dark currents increases.

The stress of the upper electrode 108 is preferably −500 MPa or higher. If the stress is controlled to be −500 MPa or higher, it is possible to reduce a level of dark currents of the photoelectric conversion element.

The compressive stress is indicated by a minus sign, and a stress of −500 MPa or higher means that the compressive stress is 500 MPa or less.

If the upper electrode 108 (transparent conductive film) is formed by sputtering, the deposition rate and stress can be controlled by changing the power to be introduced, a degree of vacuum at the time of sputtering, and positional relationship between a sputter target and a substrate.

The sealing layer 110 is a layer for preventing factors such as water or oxygen which deteriorates an organic material from intruding into the photoelectric conversion portion 106 containing the organic material. The sealing layer 110 covers the lower electrode 104, the electron blocking layer 114, the photoelectric conversion portion 106, and the upper electrode 108, and seals a space between the substrate 102 and the above constituents.

In the photoelectric conversion element 100 constituted as above, the upper electrode 108 functions as an electrode of a light incidence site. After entering from the upper side of the upper electrode 108, the light is transmitted through the upper electrode 108 and enters the photoelectric conversion layer 112 of the photoelectric conversion portion 106, and electric charges are generated in the photoelectric conversion layer 112. Of the generated electric charges, holes move to the lower electrode 104. The holes having moved to the lower electrode 104 are converted into voltage signals and read out. In this manner, light can be converted into voltage signals and read out.

Next, the method for producing the photoelectric conversion element 100 will be described.

First, as the lower electrode 104, for example, a TiN substrate obtained by forming a TiN electrode on the substrate 102 is prepared.

In the TiN substrate, for example, TiN as a lower electrode material is formed into a film on the substrate 102 by a sputtering method in a vacuum of a predetermined degree, whereby a TiN electrode is formed as the lower electrode 104.

Thereafter, on the lower electrode 104, an electron blocking material, for example, a carbazole derivative, more preferably a bifluorene derivative, is formed into a film by means of, for example, a vacuum deposition method in a vacuum of a predetermined degree, whereby the electron blocking layer 114 constituting the photoelectric conversion portion 106 is formed.

Subsequently, onto the electron blocking layer 114, as a photoelectric material, for example, a p-type organic semiconductor material and a fullerene or a fullerene derivative are co-deposited in a vacuum of a predetermined degree, whereby the photoelectric conversion layer 112 constituting the photoelectric conversion portion 106 is formed.

Thereafter, on the photoelectric conversion layer 112, a transparent conductive oxide, for example, ITO is formed into a film having a thickness of, for example, 5 nm to 100 nm by a sputtering method at a deposition rate of 0.5 Å/s or higher. In addition to the above film formation conditions, the power introduced, a degree of vacuum at the time of sputtering, and positional relationship between a sputter target and a substrate are adjusted to form the film. In this manner, for example, the upper electrode 108 constituted with ITO is formed on the photoelectric conversion layer 112. The upper electrode 108 has a stress of −50 MPa to −500 MPa. That is, a compressive stress of 50 MPa to 500 MPa is applied to the upper electrode 108.

Next, on the upper electrode 108 and the substrate 102, as a sealing material, for example, aluminum oxide is formed into an aluminum oxide film by an ALD method in a vacuum of a predetermined degree, and then as a sealing material, for example, silicon nitride is formed into a silicon nitride film by a magnetron sputtering method in a vacuum of a predetermined degree. In this manner, the sealing layer 110 as a laminate film consisting of the aluminum oxide film and silicon nitride film is formed, and thereby, the photoelectric conversion element 100 is formed. The sealing layer 110 may be a single-layered film.

In the production method of the present embodiment, in the step of forming the upper electrode 108, the film is formed at a deposition rate of 0.5 Å/s or higher, and the stress is controlled to be −50 MPa to −500 MPa (compressive stress of 50 MPa to 500 MPa). Therefore, during the formation of the film, it is possible to inhibit oxygen gas, which is a factor deteriorating the photoelectric conversion material, from being incorporated into the photoelectric conversion layer 112. Moreover, a degree of adhesiveness between the photoelectric conversion layer 112 and the upper electrode 108 is heightened, and sufficient adhesiveness is obtained in the interface, whereby peeling of the upper electrode 108 from the photoelectric conversion layer 112 is inhibited over a long period of time. As a result, it is possible to obtain a photoelectric conversion element which shows a low level of dark currents, that is, a high SN ratio and stays stable for a long period of time.

For producing the photoelectric conversion element 100, a substrate 102 on which the lower electrode 104, the electron blocking layer 114 and the photoelectric conversion layer 112 are formed in this order may be prepared, and the upper electrode 108 may be formed on the photoelectric conversion 112.

Hereinafter, the stress of the upper electrode 108 and the method for measuring the stress will be described.

In order to describe the stress acting on a thin film 62, a substrate 60 on which the thin film 62 is formed as shown in FIGS. 2A and 2B will be used as an example. The thin film 62 corresponds to the upper electrode 108.

In FIG. 2A, the direction of a compressive stress σ_{c} acting on the thin film 62, when the substrate 60 on which the thin film 62 is formed is expanded, is indicated by arrows. When the substrate 60 is bent such that the side where the thin film 62 is formed becomes convexified as in FIG. 2A, the thin film 62 formed on the substrate 60 is expanded, and a compressive force acts on the thin film 62 adhereing to the substrate 60. This force is the compressive stress σ_{c}.

In FIG. 2B, the direction of a tensile stress σₜ acting on the thin film 62, when the substrate 60 on which the thin film 62 is formed is contracted, is indicated by arrows. When the substrate 60 is bent such that the side where the thin film 62 is formed becomes concavified as in FIG. 2B, the thin film 62 formed on the substrate 60 contracts, and a tensile force acts on the thin film 62 adhering to the substrate 60. This force is the tensile stress σₜ.

The compressive stress σ_{c} and the tensile stress at acting on the thin film 62 are influenced by a degree of warpage of the substrate 60. Based on a degree of warpage of the substrate 60, the stress can be measured using an optical lever method.

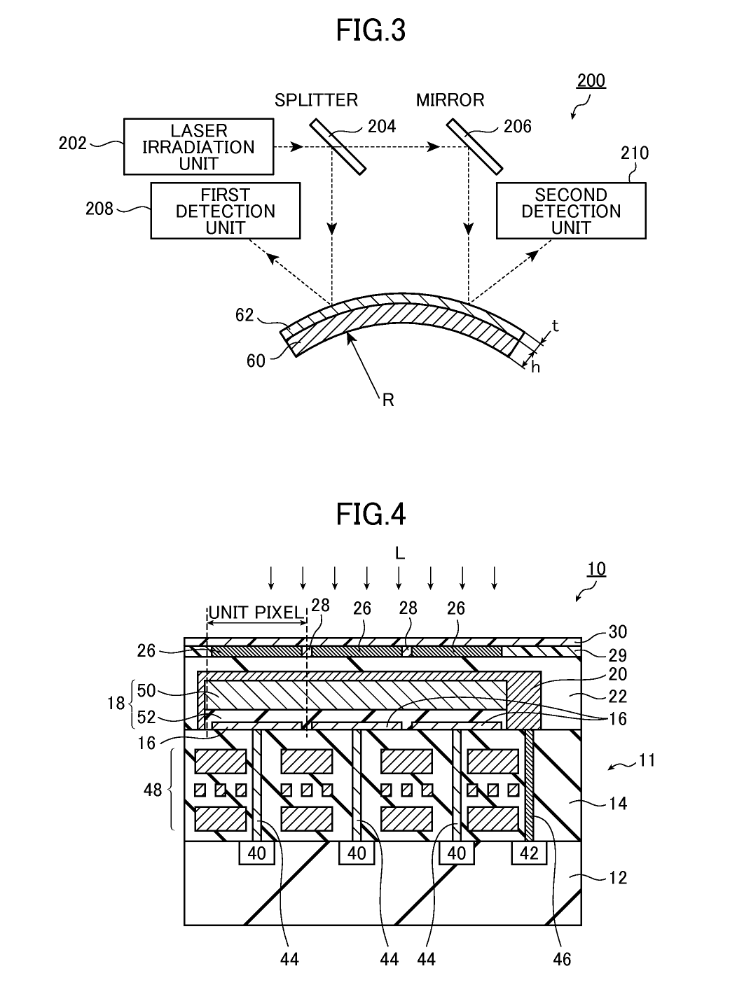

FIG. 3 is a schematic view showing an apparatus for measuring a degree of warpage of the substrate on which a thin film is formed. A measurement apparatus 200 shown in FIG. 3 has a laser irradiation unit 202 that emits laser light, a splitter 204 that reflects a portion of light emitted from the laser irradiation unit 202 and transmits the other portion thereof, and a mirror 206 that reflects the light transmitted through the splitter 204. The thin film 62 to be measured is formed on one surface of the substrate 60. The thin film 62 on the substrate 60 is irradiated with the light reflected by the splitter 204, and at this time, a reflection angle of the light that reflects on the surface of the thin film 62 is detected by a first detection unit 208. The thin film 62 on the substrate 60 is irradiated with the light reflected by the mirror 206, and at this time, a reflection angle of the light that reflects on the surface of the thin film 62 is detected by a second detection unit 210.

FIG. 3 shows an example in which the compressive stress acting on the thin film 62 is measured by bending the substrate 60 such that the surface of the side where the thin film 62 is formed becomes convexified. Herein, the thickness of the substrate 60 is indicated by h, and the thickness of the thin film 62 is indicated by t.

Next, the measurement procedure of the stress of the thin film by using the measurement apparatus 200 will be described.

As the apparatus used for the measurement, for example, a thin film stress measuring apparatus FLX-2320-S manufactured by Toho Technology Corporation can be used. The measurement conditions set when this apparatus is used are shown below.

Laser light (laser irradiation unit 202)

Used laser: KLA-Tencor-2320-S

Laser output power: 4 mW

Laser wavelength: 670 nm

Scanning speed: 30 mm/s

Substrate

Substrate material: silicon (Si)

Crystal orientation: <100>

Type: P type (dopant: Boron)

Thickness: 250±25 μm or 280±25 μm

Measurement procedure

A degree of warpage of the substrate 60 on which the thin film 62 will be formed is measured in advance to obtain a radius of curvature R1 of the substrate 60. Thereafter, the thin film 62 is formed on one surface of the substrate 60, and a degree of warpage of the substrate 60 is measured to obtain a radius of curvature R2. Herein, the surface of the substrate 60 on the side where the thin film 62 is formed is scanned by the laser as shown in FIG. 3, and the degree of warpage is calculated from the reflection angle of the laser light reflected by the substrate 60. Based on the obtained degree of warpage, the radius of curvature R is calculated by the following equation.

Radius of curvature R=R1·R2/(R1−R2)

Subsequently, by the following expression, the stress of the thin film 62 is calculated. The stress of the thin film 62 is indicated by a unit Pa. A compressive stress is expressed as a negative value, and a tensile stress is expressed as a positive value. The method for measuring the stress of the thin film 62 is not particularly limited, and known methods can be used.

Expression for calculating stress

σ=E×h²/6(1−ν)Rt

E/(1−ν): biaxial elastic modulus (Pa) of the base substrate

ν: Poisson ratio

h: thickness (m) of the base substrate

R: radius of curvature (m) of the base substrate

σ: average stress (Pa) of thin film

Next, an imaging device using the photoelectric conversion element 100 will be described.

FIG. 4 is a schematic cross-sectional view showing an imaging device according to an embodiment of the present invention.

The imaging device according to the embodiment of the present invention can be used for imaging apparatuses such as digital cameras and digital video cameras. The imaging device can also be used by being mounted on imaging modules and the like of electronic endoscopes, cellular phones, and the like.

An imaging device 10 shown in FIG. 4 has a substrate 12, an insulating layer 14, pixel electrodes 16, a photoelectric conversion portion 18, a counter electrode 20, a sealing layer (protective film) 22, color filters 26, partitions 28, a light shielding layer 29, and a protective layer 30.

The pixel electrode 16 corresponds to the lower electrode 104 of the aforementioned photoelectric conversion element 100, the counter electrode 20 corresponds to the upper electrode 108 of the aforementioned photoelectric conversion element 100, the photoelectric conversion portion 18 corresponds to the photoelectric conversion portion 106 of the aforementioned photoelectric conversion element 100, and the sealing layer 22 corresponds to the sealing layer 110 of the aforementioned photoelectric conversion element 100. In the substrate 12, reading circuits 40 and a voltage supply portion 42 which applies voltage to the counter electrode are formed.

As the substrate 12, for example, a glass substrate or a semiconductor substrate such as Si is used. On the substrate 12, the insulating layer 14 formed of a known insulating material is formed. On the surface of the insulating layer 14, plural pixel electrodes 16 are formed. The pixel electrodes 16 are arranged in the form being one-dimensional or two-dimensional.

Moreover, in the insulating layer 14, first connection portions 44 which connect the pixel electrodes 16 and the reading circuits 40 and a second connection portion 46 which connects the counter electrode 20 and the voltage supply portion 42 are formed. The second connection portion 46 is formed in a position not connected to the pixel electrodes 16 and the photoelectric conversion portion 18. The first connection portion 44 and the second connection portion 46 are formed of a conductive material.

In the inside of the insulating layer 14, a wiring layer 48 which is for connecting the reading circuit 40 and the voltage supply portion 42 to, for example, the outside of the imaging device 10 is formed. The wiring layer 48 is formed of a conductive material.

As described above, the pixel electrodes 16 connected to the respective first connection portions 44 are formed on a surface 14a of the insulating layer 14 on the substrate 12, and this structure is called a circuit board 11. The circuit board 11 is also called a CMOS board.

The photoelectric conversion portion 18 is formed so as to cover the plural pixel electrodes 16 and to avoid the second connection portion 46. The photoelectric conversion portion 18 has a photoelectric conversion layer 50 containing an organic substance and an electron blocking layer 52. As described above, the photoelectric conversion portion 18 corresponds to the photoelectric conversion portion 106 of the photoelectric conversion element 100 shown in FIG. 1. Accordingly, needless to say, the photoelectric conversion layer 50 and the electron blocking layer 52 correspond to the photoelectric conversion layer 112 and the electron blocking layer 114, respectively.

In the photoelectric conversion portion 18, the electron blocking layer 52 is formed at the side of the pixel electrodes 16, and the photoelectric conversion layer 50 is formed on the electron blocking layer 52.

The electron blocking layer 52 is a layer for inhibiting electrons from being injected into the photoelectric conversion layer 50 from the pixel electrodes 16.

The photoelectric conversion layer 50 generates electric charges according to the amount of received light such as incident light L and contains an organic photoelectric conversion material. The film thicknesses of the photoelectric conversion layer 50 and the electron blocking layer 52 are required to be constant only above the pixel electrodes 16. The detail of the photoelectric conversion layer 50 will be described later.

The counter electrode 20 is an electrode opposed to the pixel electrodes 16 and covers the photoelectric conversion layer 50. The photoelectric conversion layer 50 is disposed between the pixel electrodes 16 and the counter electrode 20.

The counter electrode 20 is constituted with a conductive material showing transparency with respect to the incident light so as to cause light to enter the photoelectric conversion layer 50. The counter electrode 20 is electrically connected to the second connection portion 46 disposed outside the photoelectric conversion layer 50, and is connected to the voltage supply portion 42 through the second connection portion 46.

For the counter electrode 20, the same material as that of the upper electrode 108 can be used. Accordingly, the detail of the material of the counter electrode 20 will not be described.

The voltage supply portion 42 applies predetermined voltage to the counter electrode 20 through the second connection portion 46. When the voltage which should be applied to the counter electrode 20 is higher than the power supply voltage of the imaging device 10, the voltage supply portion 42 increases the power supply voltage by using a booster circuit such as a charge pump and supplies the aforementioned predetermined voltage.

The pixel electrodes 16 are electric charge-collecting electrodes for collecting electric charges generated by the photoelectric conversion layer 50 disposed between the pixel electrodes 16 and the counter electrode 20 opposed to the pixel electrodes 16. The pixel electrodes 16 are connected to the reading circuits 40 through the first connection portions 44. The reading circuits 40 respectively correspond to the plural pixel electrodes 16 and are disposed in the substrate 12. The reading circuits 40 read out signals corresponding to the electric charges collected by the pixel electrodes 16 which correspond thereto.

For the pixel electrodes 16, the same material as that of the lower electrode 104 can be used. Accordingly, the detail of the material of the pixel electrodes 16 will not be described.

When a step difference corresponding to the film thickness of the pixel electrode 16 is steep at the edge of the pixel electrodes 16, when the surface of the pixel electrode 16 has marked concavities or convexities, or when fine dust (particles) adheres onto the pixel electrodes 16, the thickness of the photoelectric conversion layer 50 or the electron blocking layer 52 over the pixel electrodes 16 becomes smaller than a desired size or cracks occur in the layer. If the counter electrode 20 (upper electrode 108) is formed on the layers in such a state, due to the contact between the pixel electrodes 16 and the counter electrode 20 and concentration of electric field in the defective portion, pixel defectiveness such as increase of dark currents, a short circuit, or the like is caused. Moreover, the defectiveness described above may deteriorate adhesiveness between the pixel electrodes 16 and the layer over the electrodes or deteriorate heat resistance of the imaging device 10.

In order to prevent the above defectiveness and improve reliability of the element, it is preferable to control a surface roughness R of the pixel electrodes 16 to be 0.6 nm or less. The smaller the surface roughness Ra of the pixel electrodes 16 is, the smaller the concavities and convexities on the surface become, hence the surface flatness becomes excellent. Basically, it is preferable that there be no step difference corresponding to the film thickness of the pixel electrode 16. In this case, the pixel electrodes 16 are buried in the insulating layer 14, and then the pixel electrodes 16 without a step can be formed by a chemical mechanical polishing (CMP) treatment or the like. Moreover, if the edge of the pixel electrode 16 is caused to be slant, the step difference can become gentle. The slant can be formed by selecting conditions of etching treatment of the pixel electrodes 16. In order to remove particles on the pixel electrodes 16, it is particularly preferable to wash the pixel electrodes 16 and the like by using a general washing technique, which is used in a semiconductor production process, before the electron blocking layer 52 is formed.

The reading circuit 40 is constituted with, for example, a CCD, MOS or TFT circuit, and shielded from light by a light shielding layer (not shown in the drawing) disposed inside the insulating layer 14. In order to be used for a general image sensor, the reading circuits 40 is preferably constituted with a CCD or CMOS circuit. In view of noise properties and high speed, the reading circuit is preferably constituted with a CMOS circuit.

Though not shown in the drawing, for example, an n-region of a high concentration that is surrounded by a p-region is formed in the substrate 12. The n-region is connected to the first connection portions 44, and the reading circuits 40 are disposed in the p-region. The n-region functions as an electric charge accumulating portion that accumulates the electric charges of the photoelectric conversion layer 50. Signal electric charges accumulated in the n-region are converted into signals by the reading circuits 40 according to the electric charge amount, and output to the outside of the imaging device 10 through, for example, the wiring layer 48.

The sealing layer 22 is for protecting the photoelectric conversion layer 50 containing an organic substance from factors such as water molecules causing deterioration. The sealing layer 22 is formed to cover the counter electrode 20.

For the sealing layer 22 (sealing layer 110), the following conditions are required.

First, in each step of producing the element, the sealing layer 22 is required to protect the photoelectric conversion layer by preventing intrusion of factors deteriorating the organic photoelectric conversion material, which are contained in a solution, plasma, or the like.

Second, after the element is produced, the sealing layer needs to prevent deterioration of the photoelectric conversion layer 50 while the element is being stored or used for a long period of time, by preventing intrusion of factors such as water molecules that deteriorates the organic photoelectric conversion material.

Third, at the time of formation of the sealing layer 22, the sealing layer 22 should not deteriorate the photoelectric conversion layer that has already been formed.

Fourth, since the incident light passes through the sealing layer 22 and reaches the photoelectric conversion layer 50, the sealing layer 22 should have transparency with respect to the light of a wavelength detected by the photoelectric conversion layer 50.

The sealing layer 22 (sealing layer 110) can be constituted with a thin film formed of a single material. However, if this layer has a multi-layer structure, and each of the layers is caused to function in different ways, it is possible to expect effects such as stress relaxation of the entire sealing layer 22, inhibition of occurrence of defectiveness such as cracks or pin holes caused by dust or the like rising during the production process, and ease of optimization of material development. For example, the sealing layer 22 can be constituted with two layers including a layer, which plays its original role of preventing intrusion of factors such as water molecules causing deterioration, and an “auxiliary sealing layer” which is laminated on the above-described layer and has a function that is not easily obtained from the above-described layer. The sealing layer 22 can be constituted with three or more layers. However, in respect of production costs, the smaller the number of the layers, the better.

For example, the sealing layer 22 (sealing layer 110) can be formed by the following manner.

The performance of organic photoelectric conversion materials remarkably deteriorates due to factors such as water molecules causing the deterioration. Accordingly, the entire photoelectric conversion layer needs to be sealed by being covered with dense metal oxide film, metal nitride film, metal oxynitride film and the like that do not allow permeation of water molecules. Conventionally, aluminum oxide, silicon oxide, silicon nitride, silicon oxynitride, a laminate structure of these, a laminate structure constituted with these and an organic polymer, and the like are formed into a sealing layer by various vacuum film formation techniques. In the conventional sealing layer, a thin film does not easily grow in the portions of step difference due to structures on the substrate surface, minute defectiveness on the substrate surface, particles adhering onto the substrate surface, and the like (because the step differences cast a shadow). Consequently, the film thickness in these portions are markedly smaller than in a flat portion, hence the portion of step difference becomes a route through which the factors causing deterioration permeates. In order to completely cover the step differences with the sealing layer 22, a film having a thickness of 1 μm or more needs to be formed in the flat portion to make the entire sealing layer 22 become thick.

In the imaging device 10 having a pixel size of less than 2 μm, particularly, having a pixel size of about 1 μm, if a distance between the color filter 26 and the photoelectric conversion layer 50, that is, the thickness of the sealing layer 22 is large, the incident light is diffracted or diverges inside the sealing layer 22, and color mixture occurs. Therefore, for the imaging device 10 having a pixel size of about 1 μm, a material of and a producing method for a sealing layer, which may not deteriorate the pixel performance even if the thickness of the entire sealing layer 22 is reduced, are necessary.

An atomic layer deposition (ALD) method is sort of a CVD method, and is a technique of forming a thin film by alternately repeating a reaction caused by adsorption of organic metal compound molecules, metal halide molecules, and metal hydride molecules, which are thin film materials, onto the substrate surface, and decomposition of unreacted groups contained in the above materials. When reaching the substrate surface, the thin film material is in the state of low-molecular weight material, and accordingly, a thin film can grow as long as there is an extremely small space into which the low-molecular weight material can penetrate. Consequently, the portion of step difference can be completely covered (the thickness of the thin film having grown in the portion of step difference becomes the same as the thickness of the thin film having grown in the flat portion), unlike in the conventional thin film formation method having difficulties in doing this. That is, the atomic layer deposition (ALD) method is extremely excellent in step difference covering properties. Therefore, since step differences due to structures on the substrate surface, minute defectiveness on the support surface, particles adhering onto the substrate surface, and the like can be completely covered, the aforementioned portion of step difference does not become a route through which factors causing deterioration of the photoelectric conversion material intrude. When the sealing layer 22 is formed by the atomic layer deposition (ALD) method, it is possible to more effectively reduce the film thickness of the sealing layer compared to the conventional technique.

When the sealing layer 22 is formed by the atomic layer deposition method, materials proper for the above preferable sealing layer can be appropriately selected. However, the materials are limited to materials which may not deteriorate the organic photoelectric conversion material and can grow into a thin film at a relatively low temperature. If alkyl aluminum or aluminum halide is used for the atomic layer deposition method, it is possible to form a dense aluminum oxide thin film at a temperature of lower than 200° C. at which the organic photoelectric conversion material does not deteriorate. Particularly, use of trimethyl aluminum is preferable since this makes it possible to form an aluminum oxide thin film even at a temperature of about 100° C. Silicon oxide or titanium oxide is also preferable since this makes it possible to form a dense thin film as the sealing layer 22 at a temperature of lower than 200° C. similarly to aluminum oxide by appropriately selecting materials.

If the thin film is formed by the atomic layer deposition method, a thin film with excellent quality that is unsurpassed in view of step difference covering properties and density can be formed at a low temperature. However, the thin film deteriorates in some cases due to chemicals used in a photolithography process. For example, an aluminum oxide thin film formed by the atomic layer deposition method is amorphous, hence the surface thereof is corroded by an alkaline solution such as a developer or stripper. In this case, a thin film having excellent chemical resistance needs to be disposed on the aluminum oxide thin film formed by the atomic layer deposition film method. That is, an auxiliary sealing layer as a functional film protecting the sealing layer 22 is necessary.

Particularly, it is preferable to employ a constitution in which a second sealing layer, which is formed by a sputtering method and contains any one of aluminum oxide, silicon oxide, silicon nitride, and silicon oxynitride, is placed on a first sealing layer (sealing layer 22). Moreover, the film thickness of the sealing layer 22 (first sealing layer) is preferably from 0.05 μm to 0.2 μm. Furthermore, it is preferable for the sealing layer 22 (first sealing layer) to contain any one of the aluminum oxide, silicon oxide, and titanium oxide.

The color filter 26 is formed in the position opposed to each of the pixel electrodes 16 on the sealing layer 22. The partition 28 is disposed between the color filters 26 on the sealing layer 22, and is for improving light transmission efficiency of the color filters 26. The light shielding layer 29 is formed on the sealing layer 22, in a position not included in the area where there are the color filters 26 and the partitions 28 (area of valid pixels). The light shielding layer 29 prevents light from entering the photoelectric conversion layer 50 formed in a position not included in the area of valid pixels.

The protective layer 30 is for protecting the color filters 26 during the subsequent steps and the like, and is formed to cover the color filters 26, partitions 28, and the light shielding layer 29. The protective layer 30 is also called an over coat layer.

In the imaging device 10, one pixel electrode 16 on which the photoelectric conversion portion 18, the counter electrode 20, and the color filter 26 are formed is a unit pixel.

For the protective layer 30, polymer materials such as acrylic resins, polysiloxane-based resins, polystyrene-based resins, or fluororesins and inorganic materials such as silicon oxide or silicon nitride can be used appropriately. If photosensitive resins such as polystyrene-based resins are used, the protective layer 30 can be subjected to patterning by a photolithography method. Therefore, this is preferable since it makes it easy to use such resins as a photoresist when a peripheral portion of the light shielding layer, the sealing layer, the insulating layer, and the like on a bonding pad are opened, and to process the protective layer 30 itself into a microlens. Meanwhile, the protective layer 30 can be used as an antireflection layer, and it is preferable to form various low-refractive index materials used as the partitions 28 of the color filters 26 into a film. Moreover, in order to obtain the function of the protective layer during the subsequent steps performed later and the function of the antireflection layer, the protective layer 30 can be constituted with two or more layers composed of a combination of the above materials.

In the present embodiment, the pixel electrodes 16 are formed on the surface of the insulating layer 14. However, the present invention is not limited thereto, and the pixel electrodes 16 may be buried in the surface of the insulating layer 14. In addition, the imaging device has a single second connection portion 46 and a single voltage supply portion 42, but the imaging device may have a plurality of these portions. For example, if voltage is supplied to the counter electrode 20 from both ends of the counter electrode 20, it is possible to suppress a voltage drop of the counter electrode 20. The number of a set of the second connection portion 46 and the voltage supply portion 42 may be appropriately increased or decreased, in consideration of a chip area of the device.

Next, the method for producing the imaging device 10 according to the embodiment of the present invention will be described.

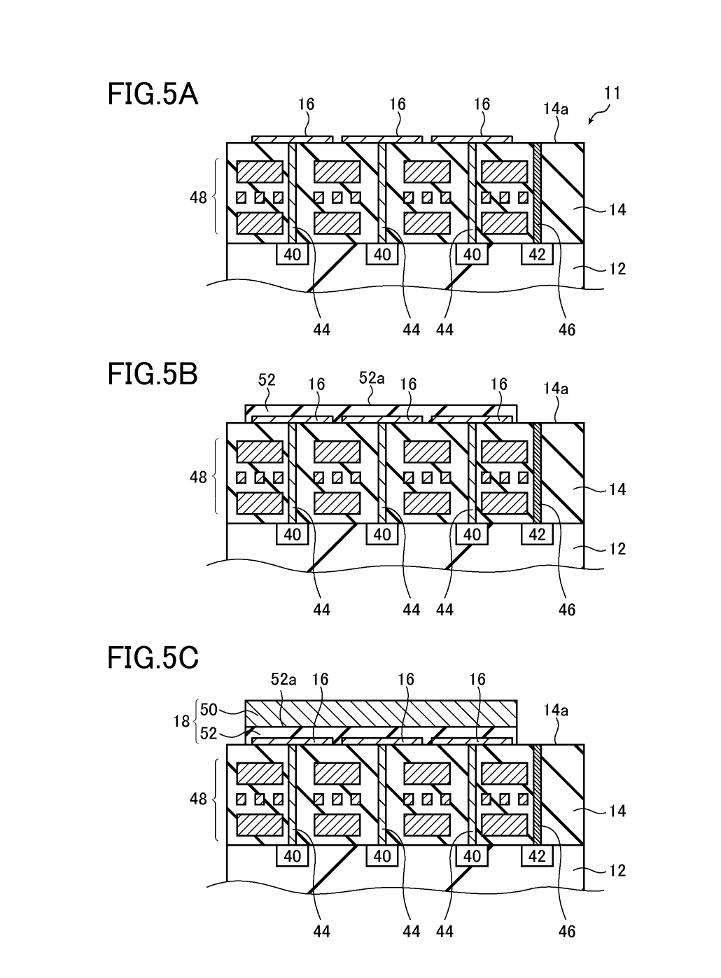

In the method for producing the imaging device 10 according to the embodiment of the present invention, first, as shown in FIG. 5A, the circuit board 11 (CMOS board) is prepared. In the circuit board 11, the insulating layer 14, in which the first connection portions 44, the second connection portion 46, and the wiring layer 48 have been formed, is formed on the substrate 12 on which the reading circuits 40 and the voltage supply portion 42 that applies voltage to the counter electrode 20 have been formed, and further, the pixel electrodes 16 connected to the respective first connection portions 44 are formed on the surface 14a of the insulating layer 14. In this case, as described above, the first connection portions 44 are connected to the reading circuits 40, and the second connection portion 46 is connected to the voltage supply portion 42. The pixel electrodes 16 are formed of, for example, TiN.

Subsequently, the circuit board 11 is transported along a predetermined transport path to a film formation chamber (not shown in the drawing) for forming the electron blocking layer 52. As shown in FIG. 5B, an electron blocking material is formed into a film by, for example, a deposition method in a vacuum of a predetermined degree such that the film covers all the pixel electrodes 16 except for the portion on the second connection portion 46, whereby the electron blocking layer 52 is formed. As the electron blocking material, for example, carbazole derivatives and more preferably bifluorene derivatives are used.

The resultant is then transported along a predetermined transport path to a film formation chamber (not shown in the drawing) for forming the photoelectric conversion layer 50. As shown in FIG. 5C, on a surface 52a of the electron blocking layer 52, the photoelectric conversion layer 50 is formed by, for example, a deposition method in a vacuum of a predetermined degree. As the photoelectric conversion material, for example, a p-type organic semiconductor material and a fullerene or a fullerene derivative are used. In this manner, the photoelectric conversion layer 50 is formed to form the photoelectric conversion portion 18.

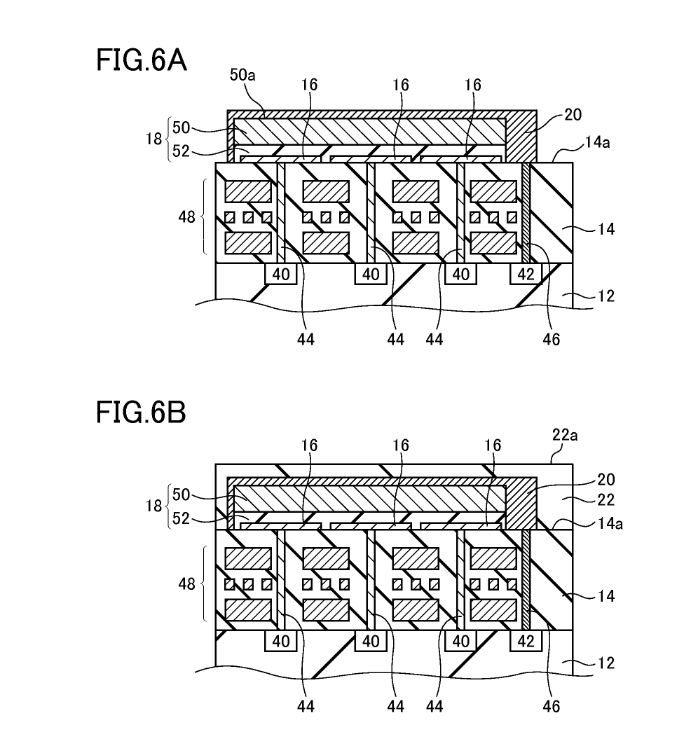

Thereafter, the resultant is transported along a predetermined transport path to a film formation chamber (not shown in the drawing) for forming the counter electrode 20. Subsequently, as shown in FIG. 6A, as the pattern to cover the photoelectric conversion portion 18 and to be formed on the second connection portion 46, the counter electrode 20 is formed by, for example, a sputtering method in a vacuum of a predetermined degree.

For forming the counter electrode 20, for example, ITO is used as a transparent conductive oxide and formed into a film having a thickness of, for example, 5 nm to 100 nm at a deposition rate of 0.5 Å/s or higher by a sputtering method. In addition to the film formation conditions, power to be introduced, a degree of vacuum at the time of sputtering, and positional relationship between a sputter target and a substrate are adjusted to form the film. In this manner, for example, the counter electrode 20 constituted with ITO is formed. The counter electrode 20 has a stress of −50 MPa to −500 MPa. That is, a compressive stress of 50 MPa to 500 MPa acts on the counter electrode 20.

The resultant is then transported along a predetermined transport path to a film formation chamber (not shown in the drawing) for forming the sealing layer 22. As shown in FIG. 6B, a laminate film consisting of an aluminum oxide film and a silicon nitride film is formed as the sealing layer 22 on the surface 14a of the insulating layer 14 so as to cover the counter electrode 20.

In this case, to form the aluminum oxide film, aluminum oxide is formed into a film on the surface 14a of the insulating layer 14 by an ALD method in a vacuum of a predetermined degree. On this aluminum oxide film, for example, silicon nitride is formed into a silicon nitride film by a magnetron sputtering method in a vacuum of a predetermined degree. The sealing layer 22 may be a single-layered film.

Subsequently, on a surface 22a of the sealing layer 22, the color filters 26, the partitions 28, and the light shielding layer 29 are formed by a photolithography method. For the color filters 26, the partitions 28, and the light shielding layer 29, known materials used for organic solid-state imaging devices are used. The respective processes for forming the color filters 26, the partitions 28, and the light shielding layer 29 may be performed in a vacuum of a predetermined degree or performed in a non-vacuum environment.

Then the protective layer 30 is formed by, for example, a coating method so as to cover the color filters 26, the partitions 28, and the light shielding layer 29. In this manner, the imaging device 10 shown in FIG. 4 can be formed. For the protective layer 30, known materials used for organic solid-state imaging devices are used. The process for forming the protective layer 30 may be performed in a vacuum of a predetermined degree or performed in a non-vacuum environment.

During the production process of the imaging device 10, in the step of forming the counter electrode 20, the film is formed at a deposition rate of 0.5 Å/s or higher, and the stress is controlled to be −50 MPa to −500 MPa (a compressive stress of 50 MPa to 500 MPa). In this manner, it is possible to inhibit oxygen gas, which is a factor deteriorating the photoelectric conversion material, from being incorporated into the photoelectric conversion layer 50 during the formation of the film. Moreover, a degree of adhesiveness between the photoelectric conversion layer 50 and the counter electrode 20 is heightened, sufficient adhesiveness is obtained at the interface, and peeling of the counter electrode 20 from the photoelectric conversion layer 50 can be inhibited over a long period of time. As a result, a photoelectric conversion element which shows a sufficiently low level of dark currents and stays stable over a long period of time can be obtained.

Next, the photoelectric conversion layer 50 and the electron blocking layer 52 constituting the photoelectric conversion portion 18 will be described in more detail.

The photoelectric conversion layer 50 is constituted in the same manner as the aforementioned photoelectric conversion layer 112. The photoelectric conversion layer 50 contains a p-type organic semiconductor material and an n-type organic semiconductor material. By joining the p-type organic semiconductor material with the n-type organic semiconductor material to form a donor-acceptor interface, exciton dissociation efficiency can be increased. Therefore, the photoelectric conversion layer having a constitution in which the p-type organic semiconductor material is joined with the re-type organic semiconductor material realizes high photoelectric conversion efficiency. Particularly, the photoelectric conversion layer in which the p-type organic semiconductor material is mixed with the n-type organic semiconductor material is preferable since the junction interface is enlarged, and the photoelectric conversion efficiency is improved.

The p-type organic semiconductor material (compound) is a donor-type organic semiconductor material (compound). This material is mainly represented by a hole-transporting organic compound and refers to an organic compound that easily donates electrons. More specifically, when two organic materials are used by being brought into contact to each other, an organic compound having a smaller ionization potential is called the p-type organic semiconductor material. Accordingly, as the donor-type organic compound, any organic compounds can be used as long as they have electron-donating properties. For example, it is possible to use a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a cyanine compound, a merocyanine compound, an oxonol compound, a polyamine compound, an indole compound, a pyrrole compound, a pyrazole compound, a polyarylene compound, condensed aromatic carbon ring compounds (naphthalene derivatives, anthracene derivatives, phenanthrene derivatives, tetracene derivatives, pyrene derivatives, perylene derivatives, and fluoranthene derivatives), metal complexes having nitrogen-containing heterocyclic compounds as ligands, and the like. The donor-type organic compound is not limited to these, and as described above, any of organic compounds having a smaller ionization potential compared to organic compounds used as n-type (acceptor-type) compounds may be used as the donor-type organic compound.

The n-type organic semiconductor material (compound) is an acceptor-type organic semiconductor material. This material is mainly represented by an electron-transporting organic compound and refers to an organic compound that easily accepts electrons. More specifically, when two organic compounds are used by being brought into contact to each other, an organic compound showing a higher degree of electron affinity is called the n-type organic semiconductor material. Accordingly, as the acceptor-type organic compound, any organic compounds can be used as long as they have electron-accepting properties. For example, it is possible to use condensed aromatic carbon ring compounds (naphthalene derivatives, anthracene derivatives, phenanthrene derivatives, tetracene derivatives, pyrene derivatives, perylene derivatives, and fluoranthene derivatives), 5 to 7-membered heterocyclic compounds containing nitrogen atoms, oxygen atoms, or sulphur atoms (for example, pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrrolidine, pyrrolopyridine, thiadiazolopyridine, dibenzazepine, and tribenzazepine), a polyarylene compound, a fluorene compound, a cyclopentadiene compound, a silyl compound, metal complexes having nitrogen-containing heterocyclic compounds as ligands, and the like. The acceptor-type organic compound is not limited to these, and as described above, any of organic compounds showing a higher degree of electron affinity compared to organic compounds used as p-type (donor-type) compounds may be used as the acceptor-type organic compound.

As the p-type organic semiconductor material or the n-type organic semiconductor material, any organic dye may be used. However, preferable examples thereof include cyanine dyes, styryl dyes, hemicyanine dyes, merocyanine dyes (including zero-methine merocyanine (simple merocyanine)), trinuclear merocyanine dyes, tetranuclear merocyanine dyes, rhodacyanine dyes, complex cyanine dyes, complex merocyanine dyes, allopolar dyes, oxonol dyes, hemioxonol dyes, squarylium dyes, croconium dyes, azamethine dyes, coumarin dyes, arylidene dyes, anthraquinone dyes, triphenylmethane dyes, azo dyes, azomethane dyes, spiro compounds, metallocene dyes, fluorenone dyes, fulgide dyes, perylene dyes, perinone dyes, phenazine dyes, phenothiazine dyes, quinone dyes, diphenylmethane dyes, polyene dyes, acridine dyes, acridinone dyes, diphenylamine dyes, quinacridone dyes, quinophthalone dyes, phenoxazine dyes, phthaloperylene dyes, diketopyrrolopyrrole dyes, dioxane dyes, porphyrin dyes, chlorophyll dyes, phthalocyanine dyes, metal complex dyes, and condensed aromatic carbon ring-based dyes (naphthalene derivatives, anthracene derivatives, phenanthrene derivatives, tetracene derivatives, pyrene derivatives, perylene derivatives, and fluoranthene derivatives).

As the n-type organic semiconductor material, it is particularly preferable to use a fullerene or a fullerene derivative having excellent electron transport properties. Fullerene refers to fullerene C₆₀, fullerene C₇₀, fullerene C₇₆, fullerene C₇₈, fullerene C₈₀, fullerene C₈₂, fullerene C₈₄, fullerene C₉₀, fullerene C₉₆, fullerene C₂₄₀, fullerene C₅₄₀, mixed fullerene, or fullerene nanotubes, and fullerene derivatives refer to compounds obtained when a substituent is added to the fullerene.

As the substituent of the fullerene derivatives, alkyl groups, aryl groups, or heterocyclic groups are preferable. As the alkyl groups, alkyl groups having 1 to 12 carbon atoms are more preferable. As the aryl and heterocyclic groups, benzene rings, naphthalene rings, anthracene rings, phenanthrene rings, fluorene rings, triphenylene rings, naphthacene rings, biphenyl rings, pyrrole rings, furan rings, thiophene rings, imidazole rings, oxazole rings, thiazole rings, pyridine rings, pyrazine rings, pyrimidine rings, pyridazine rings, indolizine rings, indole rings, benzofuran rings, benzothiophene rings, isobenzofuran rings, benzimidazole rings, imidazopyridine rings, quinolizine rings, quinoline rings, phthalazine rings, naphthyridine rings, quinoxaline rings, quinoxazoline rings, isoquinoline rings, carbazole rings, phenanthridine rings, acridine rings, phenanthroline rings, thianthrene rings, chromene rings, xanthene rings, phenoxathiin rings, phenothiazine rings, or phenazine rings are preferable, benzene rings, naphthalene rings, anthracene rings, phenanthrene rings, pyridine rings, imidazole rings, oxazole rings, or thiazole rings are more preferable, and benzene rings, naphthalene rings, or pyridine rings are particularly preferable. These may further contain a substituent, and the substituent may bind to form a ring as much as possible. Moreover, the above substituents may have plural substituents which may be the same as or different from each other. The plural substituents may bind to form a ring as much as possible.

If the photoelectric conversion layer contains a fullerene or a fullerene derivative, electrons generated by photoelectric conversion can be rapidly transported to the pixel electrodes 16 or the counter electrode 20 via fullerene molecules or fullerene derivative molecules. If the fullerene molecules or fullerene derivative molecules line up and form the pathway of electrons in this state, electron transport properties are improved, whereby high-speed responsiveness of the photoelectric conversion element can be realized. In order to achieve the above improvement, it is preferable for the photoelectric conversion layer to contain a fullerene or a fullerene derivative in a proportion of 40% (volumetric proportion) or more. However, if the proportion of a fullerene or a fullerene derivative is too high, the proportion of the p-type organic semiconductor is reduced, and the junction interface becomes small, whereby the exciton dissociation efficiency is reduced.

For the photoelectric conversion layer 50, it is particularly preferable to use triarylamine compounds, which are disclosed in JP 4213832 B and the like, as the p-type organic semiconductor material mixed with a fullerene or a fullerene derivative, since a high SN ratio of the photoelectric conversion element can be realized. If the proportion of a fullerene or a fullerene derivative in the photoelectric conversion layer is too high, the proportion of the triarylamine compounds is reduced, and the amount of absorbed incident light decreases. Since the photoelectric conversion efficiency is reduced for this reason, it is preferable for the proportion of a fullerene or a fullerene derivative contained in the photoelectric conversion layer to be 85% (volumetric proportion) or less.

The p-type organic semiconductor material used for the photoelectric conversion layer 50 is particularly preferably compounds represented by the following General formula (1).

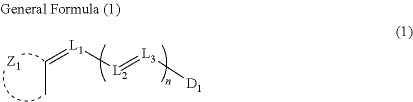

In General formula (1), Z₁ is a ring which contains at least two carbon atoms, and represents a 5-membered ring, a 6-membered ring, or a condensed ring which contains at least one of 5-membered ring and 6-membered ring. Each of L₁, L₂, and L₃ independently represents unsubstituted methine groups or substituted methine groups. D₁ represents an atomic group. n represents an integer of 0 or greater.

Z₁ is a ring which contains at least two carbon atoms, and represents a 5-membered ring, a 6-membered ring, or a condensed ring which contains at least one of 5-membered ring and 6-membered ring. As the 5-membered ring, the 6-membered ring, or the condensed ring which contains at least one of 5-membered ring and 6-membered ring, rings which are usually used as an acidic nucleus in merocyanine dyes are preferable, and specific examples thereof include the following.
(a) 1,3-Dicarbonyl nuclei: for example, a 1,3-indandione nucleus, 1,3-cyclohexanedione, 5,5-dimethyl-1,3-cyclohexanedione, and 1,3-dioxane-4,6-dione
(b) Pyrazolinone nuclei: for example, 1-phenyl-2-pyrazolin-5-one, 3-methyl-1-phenyl-2-pyrazolin-5-one, and 1-(2-benzothiazolyl)-3-methyl-2-pyrazolin-5-one
(c) Isoxazolinone nuceli: for example, 3-phenyl-2-isoxazolin-5-one, and 3-methyl-2-isoxazolin-5-one
(d) Oxindole nuclei: for example, 1-alkyl-2,3-dihydro-2-oxindole
(e) 2,4,6-Triketohexahydropyrimidine nuclei: for example, barbituric acid or 2-thiobarbituric acid and derivatives thereof; Examples of the derivatives include 1-alkyl compounds such as 1-methyl and 1-ethyl, 1,3-dialkyl compounds such as 1,3-dimethyl, 1,3-diethyl, and 1,3-dibutyl, 1,3-diaryl compounds such as 1,3-diphenyl, 1,3-di(p-chlorophenyl), and 1,3-di(p-ethoxycarbonylphenyl), 1-alkyl-1-aryl compounds such as 1-ethyl-3-phenyl, 1,3-position diheterocyclic compounds such as 1,3-di(2-pyridyl), and the like.
(f) 2-Thio-2,4-thiazolidinedione nuclei: for example, rhodanine and derivatives thereof; Examples of the substituents include 3-alkylrhodanine such as 3-methylrhodanome, 3-ethylrhodanine, and 3-allylrhodanine, 3-arylrhodanine such as 3-phenylrhodanine, 3-position heterocyclic rhodanine such as 3-(2-pyridyl)rhodanine, and the like.
(g) 2-Thio-2,4-oxazolidinedione (2-thio-2,4-(3H,5H)-oxazoledione) nuclei: for example, 3-ethyl-2-thio-2,4-oxazolidinedione
(h) Thianaphthenone nuclei: for example, 3(2H)-thianaphthenone-1,1-dioxide
(i) 2-Thio-2,5-thiazolidinedione nuclei: for example, 3-ethyl-2-thio-2,5-thiazolidinedione
(j) 2,4-Thiazolidinedione nuclei: for example, 2,4-thiazolidinedione, 3-ethyl-2,4-thiazolidinedione, and 3-phenyl-2,4-thiazolidinedione
(k) Thiazolin-4-one nuclei: for example, 4-thiazolinone and 2-ethyl-4-thiazolinone
(l) 2,4-Imidazolidinedione (hydantoin) nuclei: for example, 2,4-imidazolidinedione and 3-ethyl-2,4-imidazolidinedione
(m) 2-Thio-2,4-imidazolidinedione (2-thiohydantoin) nuclei: for example, 2-thio-2,4-imidazolidinedione and 3-ethyl-2-thio-2,4-imidazolidinedione
(n) Imidazolin-5-one nuclei: for example, 2-propylmercapto-2-imidazolin-5-one
(O) 3,5-Pyrazolidinedione nuclei: for example, 1,2-diphenyl-3,5-pyrazolidinedone and 1,2-dimethyl-3,5-pyrazolidinedone
(p) Benzothiophen-3-one nuclei: for example, benzothiophen-3-one, oxobenzothiophen-3-one, and dioxobenzothiophen-3-one
(q) Indanone nuclei: for example, 1-indanone, 3-phenyl-1-indanone, 3-methyl-1-indanone, 3,3-diphenyl-1-indanone, and 3,3-dimethyl-1-indanone

As the ring formed by Z₁, 1,3-dicarbonyl nuclei, pyrazolinone nuclei, 2,4,6-triketohexahydropyrimidine nuclei (including thioketone compounds such as barbituric acid nuclei and 2-thiobarbituric acid nuclei), 2-thio-2,4-thiazolidinedione nuclei, 2-thio-2,4-oxazolidinedione nuclei, 2-thio-2,5-thiazolidinedione nuclei, 2,4-thiazolidinedione nuclei, 2,4-imidazolidinedione nuclei, 2-thio-2,4-imidazolidinedione nuclei, 2-imidazolin-5-one nuclei, 3,5-pyrazolidinedione nuclei, benzothiophen-3-one nuclei, and indanone nuclei are preferable; 1,3-dicarbonyl nuclei, 2,4,6-triketohexahydropyrimidine nuclei (including thioketone compounds such as barbituric acid nuclei and 2-thiobarbituric acid nuclei), 3,5-pyrazolidinedione nuclei, benzothiophen-3-one nuclei, and indanone nuclie are more preferable; 1,3-dicarbonyl nuclei and 2,4,6-triketohexahydropyrimidine nuclei (including thiketone compounds such as barbituric acid nuclei and 2-thiobarbituric acid nuclei) are even more preferable; and 1,3-indandione nuclei, barbituric acid nuclei, 2-thiobarbituric acid nuclei, and derivatives thereof are particularly preferable.

Each of L₁, L₂, and L₃, independently represents unsubstituted methine groups or substituted methine groups. The substituted methine groups may bind to each other to form a ring (for example, 6-membered ring such as benzene ring). Examples of substituents of the substituted methine group include a substituent W. However, it is preferable for all of L₁, L₂, and L₃ to be unsubstituted methine groups.

L₁ to L₃ may be connected to each other to form a ring, and examples of the formed ring include cyclohexene rings, cyclopentene rings, benzene rings, thiophene rings, and the like.

n represents an integer of 0 or greater, preferably represents an integer of 0 to 3, more preferably represents 0. If n is increased, the absorption wavelength region can be made to absorb light of a long wavelength, but a pyrolysis temperature is lowered. In view of appropriately absorbing light in a visible region and suppressing pyrolysis at the time of forming a film by deposition, n is preferably 0.

D₁ represents an atomic group. D₁ is preferably a group containing —NR^{a}(R^{b}), and more preferably represents arylene groups formed when —NR^{a}(R^{b}) is substituted. Each of R^{a} and Rb independently represents a hydrogen atom or a substituent.

The arylene groups represented by D₁ are preferably arylene groups having 6 to 30 carbon atoms, and are more preferably arylene groups having 6 to 18 carbon atoms. The arylene groups may have the substituent W which will be described later, and are preferably arylene groups having 6 to 18 carbon atoms that may contain alkyl groups having 1 to 4 carbon atoms. Examples thereof include phenylene groups, naphthyl groups, antrhacenylene groups, pyrenylene groups, phenanthrenylene groups, methylphenylenen groups, dimethylphenylene groups, and the like. Among these, phenylene groups or naphthyl groups are preferable.

Examples of the substituents represented by R^{a} and Rb include the substituent W which will be described later. The substituents are preferably aliphatic hydrocarbon groups (preferably alkyl and alkenyl groups which may have substituents), aryl groups (preferably phenyl groups which may have substituents), or heterocyclic groups.

The aryl groups represented by each of R^{a} and R^{b} are preferably aryl groups having 6 to 30 carbon atoms, and are more preferably aryl groups having 6 to 18 carbon atoms. The aryl groups may have substituents, and are preferably aryl groups having 6 to 18 carbon atoms that may have alkyl groups having 1 to 4 carbon atoms or aryl groups having 6 to 18 carbon atoms. Examples thereof include phenyl groups, naphthyl groups, antrhacenyl groups, pyrenyl groups, phenanthrenyl groups, methylphenyl groups dimethylphenyl groups, biphenyl groups, and the like. Among these phenyl groups and naphthyl groups are preferable.

The heterocyclic groups represented by each of R^{a} and R^{b} are preferably heterocyclic groups having 3 to 30 carbon atoms, and more preferably heterocyclic groups having 3 to 18 carbon atoms. The heterocyclic groups may have substituents, and are preferably heterocyclic groups having 3 to 18 carbon atoms that may have alkyl groups having 1 to 4 carbon atoms or aryl groups having 6 to 18 carbon atoms. Moreover, the heterocyclic groups represented by R^{a} and R^{b} preferably have a ring-condensed structure. The ring-condensed structure preferably consists of a combination of rings (the rings may be the same as each other) selected from furan rings, thiophene rings, selenophenen rings, silole rings, pyridine rings, pyrazine rings, pyrimidine rings, oxazole rings, thiazole rings, triazole rings, oxadiazole rings, and thiadiazole rings. The heterocyclic groups are preferably quinoline rings, isoquinoline rings, benzothiophene rings, dibenzothiophene rings, thienothiophene rings, bithienobenzene rings, and bithienothiophene rings.

The arylene and aryl groups represented by D₁, R^{a}, and R^{b} are preferably benzene rings or preferably have a ring-condensed structure. The arylene and aryl groups more preferably have a ring-condensed structure having benzene rings. Examples thereof include naphthalene rings, anthracene rings, pyrene rings, and phenanthrene rings. Among these, benzene rings, naphthalene rings, and anthracene rings are preferable, and benzene rings and naphthalene rings are more preferable.

Examples of the substituent W include halogen atoms, alkyl groups (including cycloalkyl groups, bicycloalkyl groups, and tricycloalkyl groups), alkenyl groups (including cycloalkenlyl groups and bicycloalkenyl groups), alkynyl groups, aryl groups, heterocyclic groups, cyano groups, hydroxy groups, nitro groups, carboxy groups, alkoxy groups, aryloxy groups, silyloxy groups, heterocyclic oxy groups, acyloxy groups, carbamoyloxy groups, alkoxycarbonyl groups, aryloxycarbonyl groups, amino groups (including anilino groups), ammonio groups, acylamino groups, aminocarbonylamino groups, alkoxycarbonylamino groups, aryloxycarbonylamino groups, sulfamoylamino groups, alkyl and aryl sulfonylamino groups, mercapto groups, alkylthio groups, arylthio groups, heterocyclic thio groups, sulfamoyl groups, sulfo groups, alkyl and aryl sulfinyl groups, alkyl and aryl sulfonyl groups, acyl groups, aryloxycarbonyl groups, alkoxycarbonyl groups, carbamoyl groups, aryl and heterocyclic azo groups, imide groups, phosphino groups, phosphinyl groups, phosphinyloxy groups, phosphinylamino groups, phosphono groups, silyl groups, hydrazino groups, ureido groups, boronic acid groups (—B(OH)₂), phosphato groups (—OPO(OH)₂), sulphato groups (—OSO₃H), and other known substituents.

When R^{a} and Rb represent substituents (preferably alkyl groups and alkenyl groups), these substituents may bind to hydrogen atoms or substituents of an aromatic skeleton (preferably benzene ring) of aryl groups, which are formed when —NR^{a} (R^{b}) is substituted, to form a ring (preferably a 6-membered ring).

The substituents of R^{a} and Rb may bind to each other to form a ring (preferably a 5- or 6-membered ring, and more preferably a 6-membered ring). Moreover, each of R^{a} and Rb may bind to substituents in L (one of L₁, L₂, and L₃) to form a ring (preferably a 5- or 6-membered ring, and preferably a 6-membered ring).

The compounds represented by General formula (1) are the compounds disclosed in JP 2000-297068 A. Even compounds that are not disclosed in the above document can also be produced based on the synthesis method disclosed in the document. The compounds represented by General formula (1) are preferably compounds represented by General formula (2).

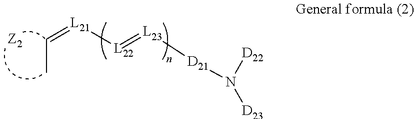

In General formula (2), Z₂, L₂₁, L₂₂, L₂₃, and n have the same definition as Z₁, L₁, L₂, L₃, and n in General formula (1), and preferable examples thereof are also the same. D₂₁ represents substituted or unsubstituted arylene groups. Each of D₂₂ and D₂₃ independently represents substituted or unsubstituted aryl groups or substituted or unsubstituted heterocyclic groups.

The arylene groups represented by D₂₁ have the same definition as the arylene groups represented by D₁, and preferable examples thereof are also the same. The aryl groups represented by each of D₂₂ and D₂₃ have the same definition as the heterocyclic groups represented by R^{a} and R^{b}, and preferable examples thereof are also the same.

Preferable and specific examples of the compounds represented by General formula (1) will be described below by using General formula (3), but the present invention is not limited thereto.

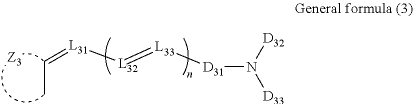

In General formula (3), Z₃ represents one of A-1 to A-12 described in the following Table 1. L₃₁ represents methylene, n represents 0. D₃₁ represents one of B-1 to B-9, and D₃₂ and D₃₃ represent one of C-1 to C-16. As Z₃, A-2 is preferable, and D₃₂ and D₃₃ are preferably selected from C-1, C-2, C-15, and C-16. D₃₁ is preferably B-1 or B-9.

In Table 1, “*” represents a binding site.

TABLE 1

| | |
|---|---|
| 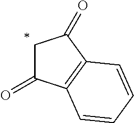 [SMILES: O=C1CC(=O)c2ccccc21] | A-1 |
| 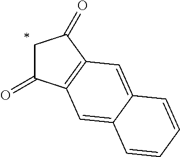 [SMILES: O=C1CC(=O)c2cc3ccccc3cc21] | A-2 |
| 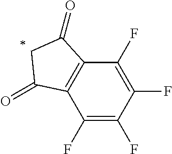 [SMILES: O=C1CC(=O)c2c(F)c(F)c(F)c(F)c21] | A-3 |
| 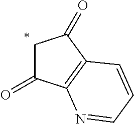 [SMILES: O=C1CC(=O)c2ncccc21] | A-4 |
| 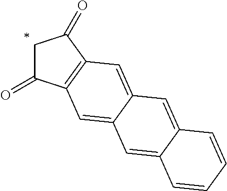 [SMILES: O=C1CC(=O)c2cc3cc4ccccc4cc3cc21] | A-5 |
| 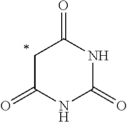 | A-6 |
| 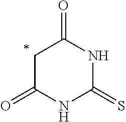 | A-7 |
| 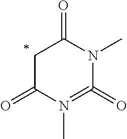 | A-8 |
| 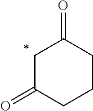 | A-9 |
| 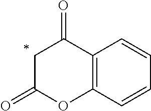 [SMILES: O=C1CC(=O)c2ccccc2O1] | A-10 |
| 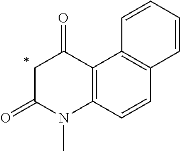 [SMILES: CN1C(=O)CC(=O)c2c1ccc1ccccc21] | A-11 |
| 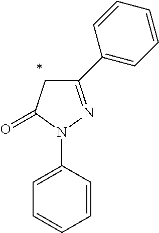 [SMILES: O=C1CC(c2ccccc2)=NN1c1ccccc1] | A-12 |
| 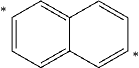 | B-1 |
| 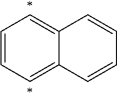 | B-2 |
| 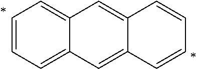 [SMILES: c1ccc2cc3ccccc3cc2c1] | B-3 |
| 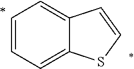 | B-4 |
| 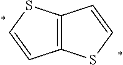 | B-5 |
| 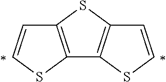 [SMILES: c1cc2sc3ccsc3c2s1] | B-6 |
| 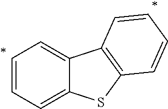 [SMILES: c1ccc2c(c1)sc1ccccc12] | B-7 |
| 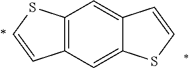 [SMILES: c1cc2cc3sccc3cc2s1] | B-8 |
| 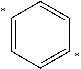 | B-9 |
| 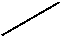 | 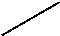 |
| 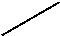 | 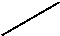 |
| 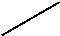 | 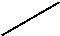 |
| 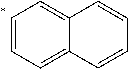 | C-1 |
| 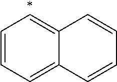 | C-2 |
| 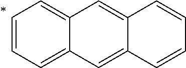 [SMILES: c1ccc2cc3ccccc3cc2c1] | C-3 |
| 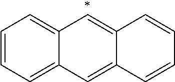 [SMILES: c1ccc2cc3ccccc3cc2c1] | C-4 |
| 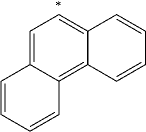 [SMILES: c1ccc2c(c1)ccc1ccccc12] | C-5 |
| 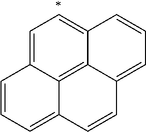 [SMILES: c1cc2ccc3cccc4ccc(c1)c2c34] | C-6 |
| 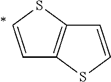 | C-7 |
| 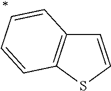 | C-8 |
| 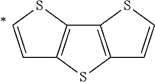 [SMILES: c1cc2sc3ccsc3c2s1] | C-9 |
| 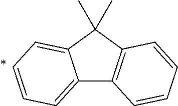 | C-10 |
| 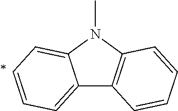 | C-11 |
| 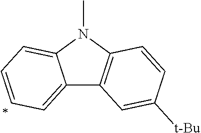 [SMILES: Cn1c2ccccc2c2cc(C(C)(C)C)ccc21] | C-12 |
| 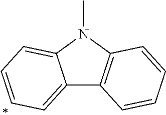 | C-13 |
| 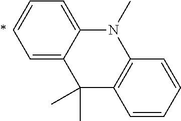 [SMILES: CN1c2ccccc2C(C)(C)c2ccccc21] | C-14 |
| 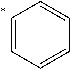 | C-15 |
| 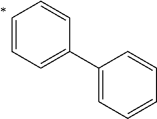 [SMILES: c1ccc(-c2ccccc2)cc1] | C-16 |
| | 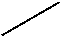 |
| | 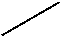 |

Examples of particularly preferable p-type organic materials include dyes or materials having not more than 4 ring-condensed structures (materials having 0 to 4 ring-condensed structures and preferably having 1 to 3 ring-condensed structures). If pigment-based p-type materials that are generally used for organic thin film solar cells are used, a level of dark currents in a pn interface tends to increase, and optical response tends to become slow due to trapping caused in a crystalline grain boundary. Accordingly, it is difficult to use the aforementioned pigment-based p-type materials for an imaging device. Therefore, dye-based p-type materials that are not easily crystallized or materials that have not more than 4 ring-condensed structures can be preferably used for the imaging device.

More preferable examples of the compounds represented by General formula (1) include combinations of the following substituents, linking groups, and partial structures in General formula (3) as shown in Table 2, but the present invention is not limited thereto.

TABLE 2

| Compound | 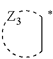 | L₃₁ | n | D₃₁ | D₃₂ | D₃₃ |
|---|---|---|---|---|---|---|
| 1 | A-1 | CH | 0 | B-9 | C-1 | C-1 |
| 2 | A-2 | CH | 0 | B-1 | C-1 | C-1 |
| 3 | A-3 | CH | 0 | B-9 | C-15 | C-15 |
| 4 | A-4 | CH | 0 | B-9 | C-15 | C-15 |
| 5 | A-5 | CH | 0 | B-9 | C-15 | C-15 |
| 6 | A-10 | CH | 0 | B-9 | C-15 | C-15 |
| 7 | A-11 | CH | 0 | B-9 | C-15 | C-15 |
| 8 | A-6 | CH | 0 | B-1 | C-15 | C-15 |
| 9 | A-7 | CH | 0 | B-1 | C-15 | C-15 |
| 10 | A-8 | CH | 0 | B-1 | C-15 | C-15 |
| 11 | A-9 | CH | 0 | B-1 | C-15 | C-15 |
| 12 | A-12 | CH | 0 | B-1 | C-15 | C-15 |
| 13 | A-2 | CH | 0 | B-2 | C-15 | C-15 |
| 14 | A-2 | CH | 0 | B-3 | C-15 | C-15 |
| 15 | A-2 | CH | 0 | B-9 | C-15 | C-15 |
| 16 | A-2 | CH | 0 | B-9 | C-16 | C-16 |
| 17 | A-1 | CH | 0 | B-9 | C-16 | C-16 |
| 18 | A-2 | CH | 0 | B-9 | C-1 | C-1 |
| 19 | A-2 | CH | 0 | B-1 | C-1 | C-2 |
| 20 | A-2 | CH | 0 | B-1 | C-1 | C-15 |
| 21 | A-2 | CH | 0 | B-1 | C-1 | C-3 |
| 22 | A-2 | CH | 0 | B-9 | C-15 | C-4 |
| 23 | A-2 | CH | 0 | B-9 | C-15 | C-5 |
| 24 | A-2 | CH | 0 | B-9 | C-15 | C-6 |
| 25 | A-2 | CH | 0 | B-9 | C-7 | C-7 |
| 26 | A-2 | CH | 0 | B-9 | C-8 | C-8 |
| 27 | A-2 | CH | 0 | B-1 | C-10 | C-10 |
| 28 | A-2 | CH | 0 | B-9 | C-11 | C-11 |
| 29 | A-2 | CH | 0 | B-9 | C-12 | C-12 |
| 30 | A-2 | CH | 0 | B-4 | C-15 | C-15 |
| 31 | A-2 | CH | 0 | B-5 | C-15 | C-15 |
| 32 | A-2 | CH | 0 | B-6 | C-15 | C-15 |
| 33 | A-2 | CH | 0 | B-7 | C-15 | C-15 |
| 34 | A-2 | CH | 0 | B-8 | C-15 | C-15 |

A-1 to A-12, B-1 to B-9, and C-1 to C-16 in Table 2 above have the same definition as the compounds described in Table 1. Hereinafter, particularly preferable and specific examples of the compounds represented by General formula (1) will be described, but the present invention is not limited thereto.

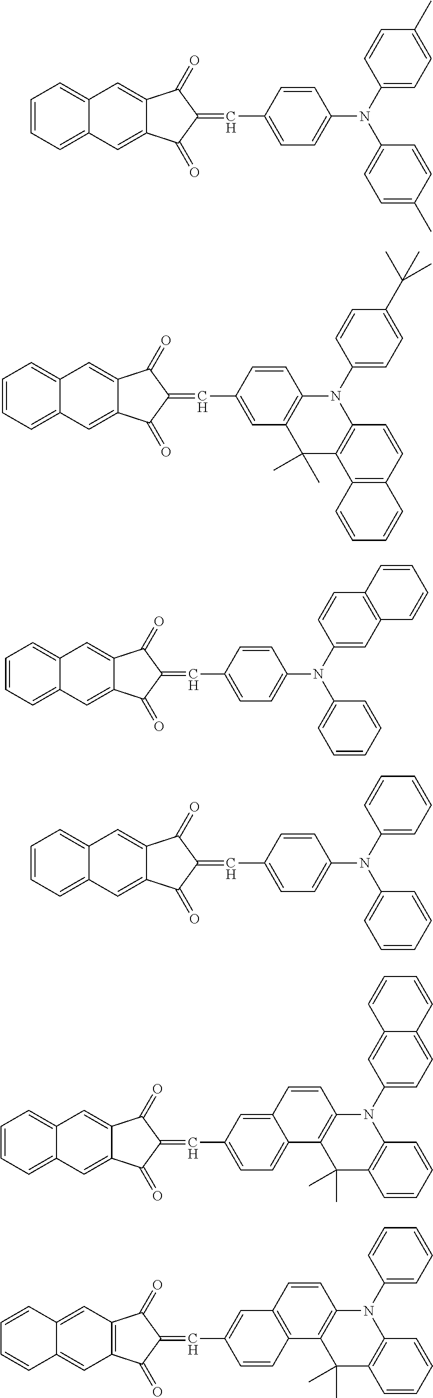

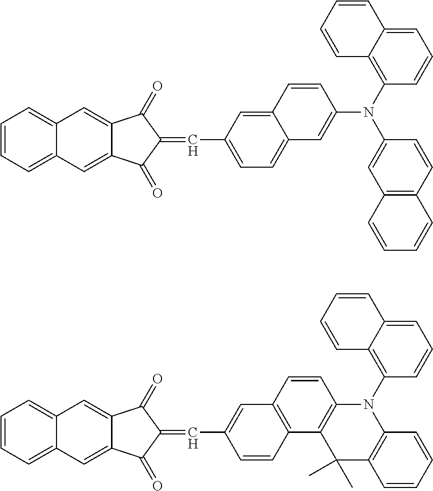

Molecular Weight

In view of film formation suitability, the molecular weight of the compounds represented by General formula (1) is preferably from 300 to 1,500, more preferably from 350 to 1,200, and even more preferably from 400 to 900. If the molecular weight is too small, the film thickness of the formed photoelectric conversion film is reduced by volatilization. On the contrary, if the molecular weight is too large, deposition cannot be performed, whereby the photoelectric conversion element cannot be prepared.

Melting Point

In view of deposition stability, the melting point of the compounds represented by General formula (1) is preferably 200° C. or higher, more preferably 220° C. or higher, and even more preferably 240° C. or higher. If the melting point is low, the compound is melted before being deposited, and a film cannot be stably formed. Moreover, a large amount of the decomposed product of the compound is generated, hence the photoelectric conversion performance deteriorates.

Absorption Spectrum

In view of absorbing a wide range of light of a visible region, the peak wavelength of the absorption spectrum of the compounds represented by General formula (1) is preferably from 400 nm to 700 nm, more preferably from 480 nm to 700 nm, and even more preferably from 510 nm to 680 nm.

Molar Absorption Coefficient of Peak Wavelength

In view of efficiently utilizing light, the higher the molar absorption coefficient of the compounds represented by General formula (1), the better. In a visible region within a wavelength range of 400 nm to 700 nm, the molar absorption coefficient in a absorption spectrum (chloroform solution) is preferably 20,000 M⁻¹ cm⁻¹ or greater, more preferably 30,000 M⁻¹ cm⁻¹ or greater, and even more preferably 40,000 M⁻¹ cm⁻¹ or greater.

Electron-donating organic materials can be used for the electron blocking layer 52. Specifically, as low-molecular weight materials, it is possible to use aromatic diamine compounds such as N,N-bis(3-methylphenyl)-(1,1′-biphenyl)-4,4′-diamine (TPD) or 4,4′-bis[N-(naphthyl)-N-phenylamino]biphenyl (α-NPD), oxazole, oxadiazole, triazole, imidazole, imidazolone, stilbene derivatives, pyrazoline derivatives, tetrahydroimidazole, polyarylalkane, butadiene, 4,4′,4″-tris(N-(3-methylphenyl)N-phenylamino)triphenylamine (m-MTDATA), porphyrin compounds such as porphine, tetraphenylporphyrin copper, phthalocyanine, copper phthalocyanine, and titanium phthalocyanine oxide, triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, silazane derivatives, carbazole derivatives, bifluorene derivatives, and the like. As high-molecular weight materials, it is possible to use polymers such as phenylene vinylene, fluorene, carbazole, indole, pyrene, pyrrole, picoline, thiophene, acetylene, and diacetylene and derivatives of these. The compounds that are not electron-donating compounds can also be used as long as they have sufficient hole transport properties.

As the electron blocking layer 52, inorganic materials can also be used. Generally, inorganic materials have a higher dielectric constant compared to organic materials. Accordingly, when inorganic materials are used for the electron blocking layer 52, higher voltage is applied to the photoelectric conversion layer, hence the photoelectric conversion efficient can be improved. Examples of materials that can form the electron blocking layer 52 include calcium oxide, chromium oxide, copper-chromium oxide, manganese oxide, cobalt oxide, nickel oxide, copper oxide, copper-gallium oxide, copper-strontium oxide, niobium oxide, molybdenum oxide, copper-indium oxide, silver-indium oxide, iridium oxide, and the like.

The present invention is basically constituted as described above. So far, the method for producing a photoelectric conversion element and the method for producing an imaging device of the present invention have been described. However, the present invention is not limited to the above embodiments. Needless to say, the present invention can be improved or modified in various ways, within a range that does not depart from the gist of the present invention.

### EXAMPLES

Hereinafter, the effects obtained in the present invention by forming the upper electrode 108 (counter electrode 20) in the form of a film at a deposition rate of 0.5 Å/s or higher and controlling the stress to be −50 MPa to −500 MPa (compressive stress of 50 MPa to 500 MPa) will be described in detail.

In the present examples, photoelectric conversion elements of Examples 1 to 8 and Comparative examples 1 to 14 were prepared to confirm the effects of the present invention. The photoelectric conversion elements were constituted with a lower electrode, an electron blocking layer, a photoelectric conversion layer, an upper electrode, a sealing layer which are formed on a substrate in this order, as shown in FIG. 1.

The prepared photoelectric conversion elements of Examples 1 to 8 and Comparative examples 1 to 14 were measured respectively in terms of the photoelectric conversion efficiency and dark currents. After the photoelectric conversion efficiency and dark currents were measured, the photoelectric conversion elements were subjected to a storage test in which they were stored for 1,000 hours at 90° C. After the storage test, the photoelectric conversion elements were measured again in terms of the photoelectric conversion efficiency and dark currents.

The following Table 3 shows the deposition rate and stress of each of the upper electrodes of Examples 1 to 8 and Comparative examples 1 to 14 and the relative sensitivity (photoelectric conversion efficiency) and level of dark currents obtained before and after the storage test.

The photoelectric conversion efficiency was expressed as a value relative to 100 as the photoelectric conversion efficiency measured before the storage test. Therefore, in the following Table 3, the photoelectric conversion efficiency is described as relative sensitivity.

The photoelectric conversion efficiency and dark currents were measured in a state where a positive bias was applied to the upper electrode side at a rate of 2.0×10⁵ V/cm.

Hereinafter, the photoelectric conversion elements of Examples 1 to 8 and Comparative examples 1 to 14 will be described.

### Example 1

Example 1 is a photoelectric conversion element in which a lower electrode, an electron blocking layer, a photoelectric conversion layer, an upper electrode, and a sealing layer are formed in this order on a substrate. The lower electrode is constituted with TiN.

The electron blocking layer was obtained by forming an organic compound represented by the following Compound 1 into a film having a thickness of 100 nm by a vacuum deposition method.

The photoelectric conversion layer was obtained by forming a mixed film which contained an organic compound represented by the following Compound 2 and fullerene C₆₀ (Compound 2:fullerene C₆₀=1:2 (volumetric ratio)) and had a film thickness of 400 nm, by co-deposition in a vacuum. Both the organic compounds were deposited at a degree of vacuum of 5.0×10⁻⁴ Pa or less and made into a film at a deposition rate of 3 Å/s.

The upper electrode was obtained by forming ITO into a film having a thickness of 10 nm by means of a DC sputtering method using a planar target at a deposition rate of 1 Å/s. For the sputtering, Ar gas was injected into a sputtering chamber having a degree of vacuum of 5.0×10⁻¹ Pa or less, and the sputtering was performed in an environment in which a degree of vacuum was set to 1 Pa and a substrate temperature at the time of film formation was set to 30° C.

The sealing layer was obtained by forming a laminate film consisting of an aluminum oxide film and a silicon nitride film. The aluminum oxide film was obtained by forming a film having a thickness of 200 nm by means of an ALD method using an atomic layer deposition apparatus (ALD apparatus). The silicon nitride film was obtained by forming a film having a thickness of 100 nm by means of a magnetron sputtering method.

The stress of the ITO film prepared under the same conditions as the upper electrode was −312 MPa (compressive stress of 312 MPa). The stress of the ITO film was obtained by forming an ITO film on the substrate 60 as described above and calculating the stress by the same calculation method as used for the aforementioned thin film 62 by using the measurement apparatus 200 shown in FIG. 3 described above.

### Example 2

An upper electrode was obtained by forming ITO into a film having a thickness of 10 nm at a deposition rate of 2 Å/s by means of a DC sputtering method. For the sputtering, Ar gas was injected into a sputtering chamber having a degree of vacuum of 5.0×10⁻⁴ Pa or less, and the sputtering was performed in an environment in which a degree of vacuum was set to 1 Pa and a substrate temperature at the time of film formation was set to 30° C. A photoelectric conversion element was prepared in the same manner as in Example 1, except that the upper electrode was formed as described above. The stress of the ITO film prepared under the same conditions as the upper electrode was −196 MPa (compressive stress of 196 MPa) which was calculated in the same manner as in Example 1.

### Example 3

An upper electrode was obtained by forming ITO into a film having a thickness of 10 nm at a deposition rate of 4 Å/s by means of a DC sputtering method. For the sputtering, Ar gas was injected into a sputtering chamber having a degree of vacuum of 5.0×10⁻⁴ Pa or less, and the sputtering was performed in an environment in which a degree of vacuum was set to 1.2 Pa and a substrate temperature at the time of film formation was set to 30° C. A photoelectric conversion element was prepared in the same manner as in Example 1, except that the upper electrode was formed as described above. The stress of the ITO film prepared under the same conditions as the upper electrode was −63 MPa (compressive stress of 63 MPa) which was calculated in the same manner as in Example 1.

### Example 4

An upper electrode was obtained by forming ITO into a film having a thickness of 10 nm at a deposition rate of 0.6 Å/s by means of a DC sputtering method. For the sputtering, Ar gas was injected into a sputtering chamber having a degree of vacuum of 5.0×10⁻⁴ Pa or less, and the sputtering was performed in an environment in which a degree of vacuum was set to 0.3 Pa and a substrate temperature at the time of film formation was set to 30° C. A photoelectric conversion element was prepared in the same manner as in Example 1, except that the upper electrode was formed as described above. The stress of the ITO film prepared under the same conditions as the upper electrode was −437 MPa (compressive stress of 437 MPa) which was calculated in the same manner as in Example 1.

### Example 5

An electron blocking layer was obtained by forming an organic compound represented by the following Compound 3 into a film having a thickness of 100 nm by a vacuum deposition method.

A photoelectric conversion layer was obtained by forming a mixed film which contained an organic compound represented by the following Compound 4 and fullerene Cho (Compound 4:fullerene C₆₀=1:2 (volumetric ratio)) and had a film thickness of 400 nm, by co-deposition in a vacuum. Both the organic compounds were deposited at a degree of vacuum of 5.0×10⁻⁴ Pa or less and made into a film at a deposition rate of 3 Å/s. A photoelectric conversion element was obtained in the same manner as in Example 1, except that the electron blocking layer and the photoelectric conversion layer were formed as described above. The stress of the ITO film prepared under the same conditions as the upper electrode was −312 MPa (compressive stress of 312 MPa) which was calculated in the same manner as in Example 1.

### Example 6

An electron blocking layer was obtained by forming an organic compound represented by the following Compound 3 into a film having a thickness of 100 nm by a vacuum deposition method.

A photoelectric conversion layer was obtained by forming a mixed film which contained an organic compound represented by the following Compound 4 and fullerene C₆₀ (Compound 4:fullerene C₆₀=1:2 (volumetric ratio)) and had a film thickness of 400 nm, by co-deposition in a vacuum. Both the organic compounds were deposited at a degree of vacuum of 5.0×10⁻⁴ Pa or less and made into a film at a deposition rate of 3 Å/s. A photoelectric conversion element was obtained in the same manner as in Example 3, except that the electron blocking layer and the photoelectric conversion layer were formed as described above. The stress of the ITO film prepared under the same conditions as the upper electrode was −63 MPa (compressive stress of 63) which was calculated in the same manner as in Example 1.

### Example 7

An electron blocking layer was obtained by forming an organic compound represented by the following Compound 5 into a film having a thickness of 100 nm by a vacuum deposition method.

A photoelectric conversion layer was obtained by forming a mixed film which contained an organic compound represented by the following Compound 6 and fullerene C₆₀ (Compound 6:fullerene C₆₀=1:3 (volumetric ratio)) and had a film thickness of 400 nm, by co-deposition in a vacuum. Both the organic compounds were deposited at a degree of vacuum of 5.0×10⁻⁴ Pa or less and made into a film at a deposition rate of 3 Å/s. A photoelectric conversion element was obtained in the same manner as in Example 1, except that the electron blocking layer and the photoelectric conversion layer were formed as described above. The stress of the ITO film prepared under the same conditions as the upper electrode was −312 MPa (compressive stress of 312 MPa) which was calculated in the same manner as in Example 1.

### Example 8

An electron blocking layer was obtained by forming an organic compound represented by the following Compound 5 into a film having a thickness of 100 nm by a vacuum deposition method.

A photoelectric conversion layer was obtained by forming a mixed film which contained an organic compound represented by the following Compound 6 and fullerene C₆₀ (Compound 6:fullerene C₆₀=1:3 (volumetric ratio)) and had a film thickness of 400 nm, by co-deposition in a vacuum. Both the organic compounds were deposited at a degree of vacuum of 5.0×10⁻⁴ Pa or less and made into a film at a deposition rate of 3 Å/s. A photoelectric conversion element was obtained in the same manner as in Example 4, except that the electron blocking layer and the photoelectric conversion layer were formed as described above. The stress of the ITO film prepared under the same conditions as the upper electrode was −437 MPa (compressive stress of 437 MPa) which was calculated in the same manner as in Example 1.

### Comparative Example 1

An upper electrode was obtained by forming ITO into a film having a thickness of 10 nm at a deposition rate of 0.4 Å/s by means of a DC sputtering method. For the sputtering, Ar gas was injected into a sputtering chamber having a degree of vacuum of 5.0×10⁻⁴ Pa or less, and the sputtering was performed in an environment in which a degree of vacuum was set to 0.2 Pa and a substrate temperature at the time of film formation was set to 30° C. A photoelectric conversion element was prepared in the same manner as in Example 1, except that the upper electrode was formed as described above. The stress of the ITO film prepared under the same conditions as the upper electrode was −397 MPa (compressive stress of 397 MPa) which was calculated in the same manner as in Example 1.

### Comparative Example 2

An upper electrode was obtained by forming ITO into a film having a thickness of 10 nm at a deposition rate of 0.3 Å/s by means of a DC sputtering method. For the sputtering, Ar gas was injected into a sputtering chamber having a degree of vacuum of 5.0×10⁻⁴ Pa or less, and the sputtering was performed in an environment in which a degree of vacuum was set to 0.2 Pa and a substrate temperature at the time of film formation was set to 30° C. A photoelectric conversion element was prepared in the same manner as in Example 1, except that the upper electrode was formed as described above. The stress of the ITO film prepared under the same conditions as the upper electrode was −442 MPa (compressive stress of 442 MPa) which was calculated in the same manner as in Example 1.

### Comparative Example 3

An upper electrode was obtained by forming ITO into a film having a thickness of 10 nm at a deposition rate of 0.1 Å/s by means of a DC sputtering method. For the sputtering, Ar gas was injected into a sputtering chamber having a degree of vacuum of 5.0×10⁻⁴ Pa or less, and the sputtering was performed in an environment in which a degree of vacuum was set to 0.2 Pa and a substrate temperature at the time of film formation was set to 30° C. A photoelectric conversion element was prepared in the same manner as in Example 1, except that the upper electrode was formed as described above. The stress of the ITO film prepared under the same conditions as the upper electrode was −473 MPa (compressive stress of 473 MPa) which was calculated in the same manner as in Example 1.

### Comparative Example 4

An upper electrode was obtained by forming ITO into a film having a thickness of 10 nm at a deposition rate of 1.2 Å/s by means of a DC sputtering method. For the sputtering, Ar gas was injected into a sputtering chamber having a degree of vacuum of 5.0×10⁻⁴ Pa or less, and the sputtering was performed in an environment in which a degree of vacuum was set to 1.5 Pa and a substrate temperature at the time of film formation was set to 30° C. A photoelectric conversion element was prepared in the same manner as in Example 1, except that the upper electrode was formed as described above. The stress of the ITO film prepared under the same conditions as the upper electrode was −31 MPa (compressive stress of 31 MPa) which was calculated in the same manner as in Example 1.

### Comparative Example 5

An upper electrode was obtained by forming ITO into a film having a thickness of 10 nm at a deposition rate of 1.4 Å/s by means of a DC sputtering method. For the sputtering, Ar gas was injected into a sputtering chamber having a degree of vacuum of 5.0×10⁻⁴ Pa or less, and the sputtering was performed in an environment in which a degree of vacuum was set to 1.5 Pa and a substrate temperature at the time of film formation was set to 30° C. A photoelectric conversion element was prepared in the same manner as in Example 1, except that the upper electrode was formed as described above. The stress of the ITO film prepared under the same conditions as the upper electrode was −39 MPa (compressive stress of 39 MPa) which was calculated in the same manner as in Example 1.

### Comparative Example 6

An upper electrode was obtained by forming ITO into a film having a thickness of 10 nm at a deposition rate of 0.9 Å/s by means of a DC sputtering method. For the sputtering, Ar gas was injected into a sputtering chamber having a degree of vacuum of 5.0×10⁻⁴ Pa or less, and the sputtering was performed in an environment in which a degree of vacuum was set to 0.3 Pa and a substrate temperature at the time of film formation was set to 30° C. A photoelectric conversion element was prepared in the same manner as in Example 1, except that the upper electrode was formed as described above. The stress of the ITO film prepared under the same conditions as the upper electrode was −546 MPa (compressive stress of 546 MPa) which was calculated in the same manner as in Example 1.

### Comparative Example 7

An upper electrode was obtained by forming ITO into a film having a thickness of 10 nm at a deposition rate of 0.8 Å/s by means of a DC sputtering method. For the sputtering, Ar gas was injected into a sputtering chamber having a degree of vacuum of 5.0×10⁻⁴ Pa or less, and the sputtering was performed in an environment in which a degree of vacuum was set to 0.3 Pa and a substrate temperature at the time of film formation was set to 30° C. A photoelectric conversion element was prepared in the same manner as in Example 1, except that the upper electrode was formed as described above. The stress of the ITO film prepared under the same conditions as the upper electrode was −611 MPa (compressive stress of 611 MPa) which was calculated in the same manner as in Example 1.

### Comparative Example 8

An upper electrode was obtained by forming ITO into a film having a thickness of 10 nm at a deposition rate of 0.7 Å/s by means of a DC sputtering method. For the sputtering, Ar gas was injected into a sputtering chamber having a degree of vacuum of 5.0×10⁻¹ Pa or less, and the sputtering was performed in an environment in which a degree of vacuum was set to 0.3 Pa and a substrate temperature at the time of film formation was set to 30° C. A photoelectric conversion element was prepared in the same manner as in Example 1, except that the upper electrode was formed as described above. The stress of the ITO film prepared under the same conditions as the upper electrode was −786 MPa (compressive stress of 786 MPa) which was calculated in the same manner as in Example 1.

### Comparative Example 9

An electron blocking layer was obtained by forming an organic compound represented by the following Compound 3 into a film having a thickness of 100 nm by a vacuum deposition method.

A photoelectric conversion layer was obtained by forming a mixed film which contained an organic compound represented by the following Compound 4 and fullerene C₆₀ (Compound 4:fullerene C₆₀=1:2 (volumetric ratio)) and had a film thickness of 400 nm, by co-deposition in a vacuum. Both the organic compounds were deposited at a degree of vacuum of 5.0×10⁻¹ Pa or less and made into a film at a deposition rate of 3 Å/s. A photoelectric conversion element was obtained in the same manner as in Comparative example 2, except that the electron blocking layer and the photoelectric conversion layer were formed as described above. The stress of the ITO film prepared under the same conditions as the upper electrode was −442 MPa (compressive stress of 442 MPa) which was calculated in the same manner as in Example 1.

### Comparative Example 10

An electron blocking layer was obtained by forming an organic compound represented by the following Compound 3 into a film having a thickness of 100 nm by a vacuum deposition method.

A photoelectric conversion layer was obtained by forming a mixed film which contained an organic compound represented by the following Compound 4 and fullerene C₆₀ (Compound 4:fullerene C₆₀=1:2 (volumetric ratio)) and had a film thickness of 400 nm, by co-deposition in a vacuum. Both the organic compounds were deposited at a degree of vacuum of 5.0×10⁻⁴ Pa or less and made into a film at a deposition rate of 3 Å/s. A photoelectric conversion element was obtained in the same manner as in Comparative example 4, except that the electron blocking layer and the photoelectric conversion layer were formed as described above. The stress of the ITO film prepared under the same conditions as the upper electrode was −31 MPa (compressive stress of 31 MPa) which was calculated in the same manner as in Example 1.

### Comparative Example 11

An electron blocking layer was obtained by forming an organic compound represented by the following Compound 3 into a film having a thickness of 100 nm by a vacuum deposition method.

A photoelectric conversion layer was obtained by forming a mixed film which contained an organic compound represented by the following Compound 4 and fullerene C₆₀ (Compound 4:fullerene C₆₀=1:2 (volumetric ratio)) and had a film thickness of 400 nm, by co-deposition in a vacuum. Both the organic compounds were deposited at a degree of vacuum of 5.0×10⁻⁴ Pa or less and made into a film at a deposition rate of 3 Å/s. A photoelectric conversion element was obtained in the same manner as in Comparative example 7, except that the electron blocking layer and the photoelectric conversion layer were formed as described above. The stress of the ITO film prepared under the same conditions as the upper electrode was −611 MPa (compressive stress of 611 MPa) which was calculated in the same manner as in Example 1.

### Comparative Example 12

An electron blocking layer was obtained by forming an organic compound represented by the following Compound 5 into a film having a thickness of 100 nm by a vacuum deposition method.

A photoelectric conversion layer was obtained by forming a mixed film which contained an organic compound represented by the following Compound 6 and fullerene C₆₀ (Compound 6:fullerene C₆₀=1:3 (volumetric ratio)) and had a film thickness of 400 nm, by co-deposition in a vacuum. Both the organic compounds were deposited at a degree of vacuum of 5.0×10⁻¹ Pa or less and made into a film at a deposition rate of 3 Å/s. A photoelectric conversion element was obtained in the same manner as in Comparative example 2, except that the electron blocking layer and the photoelectric conversion layer were formed as described above. The stress of the ITO film prepared under the same conditions as the upper electrode was −442 MPa (compressive stress of 442 MPa) which was calculated in the same manner as in Example 1.

### Comparative Example 13

An electron blocking layer was obtained by forming an organic compound represented by the following Compound 5 into a film having a thickness of 100 nm by a vacuum deposition method.

A photoelectric conversion layer was obtained by forming a mixed film which contained an organic compound represented by the following Compound 6 and fullerene Cho (Compound 6:fullerene C₆₀=1:3 (volumetric ratio)) and had a film thickness of 400 nm, by co-deposition in a vacuum. Both the organic compounds were deposited at a degree of vacuum of 5.0×10⁻¹ Pa or less and made into a film at a deposition rate of 3 Å/s. A photoelectric conversion element was obtained in the same manner as in Comparative example 5, except that the electron blocking layer and the photoelectric conversion layer were formed as described above. The stress of the ITO film prepared under the same conditions as the upper electrode was −39 MPa (compressive stress of 39 MPa) which was calculated in the same manner as in Example 1.

### Comparative Example 14

An electron blocking layer was obtained by forming an organic compound represented by the following Compound 5 into a film having a thickness of 100 nm by a vacuum deposition method.

A photoelectric conversion layer was obtained by forming a mixed film which contained an organic compound represented by the following Compound 6 and fullerene C₆₀ (Compound 6:fullerene C₆₀=1:3 (volumetric ratio)) and had a film thickness of 400 nm, by co-deposition in a vacuum. Both the organic compounds were deposited at a degree of vacuum of 5.0×10⁻⁴ Pa or less and made into a film at a deposition rate of 3 Å/s. A photoelectric conversion element was obtained in the same manner as in Comparative example 8, except that the electron blocking layer and the photoelectric conversion layer were formed as described above. The stress of the ITO film prepared under the same conditions as the upper electrode was −786 MPa (compressive stress of 786 MPa) which was calculated in the same manner as in Example 1.

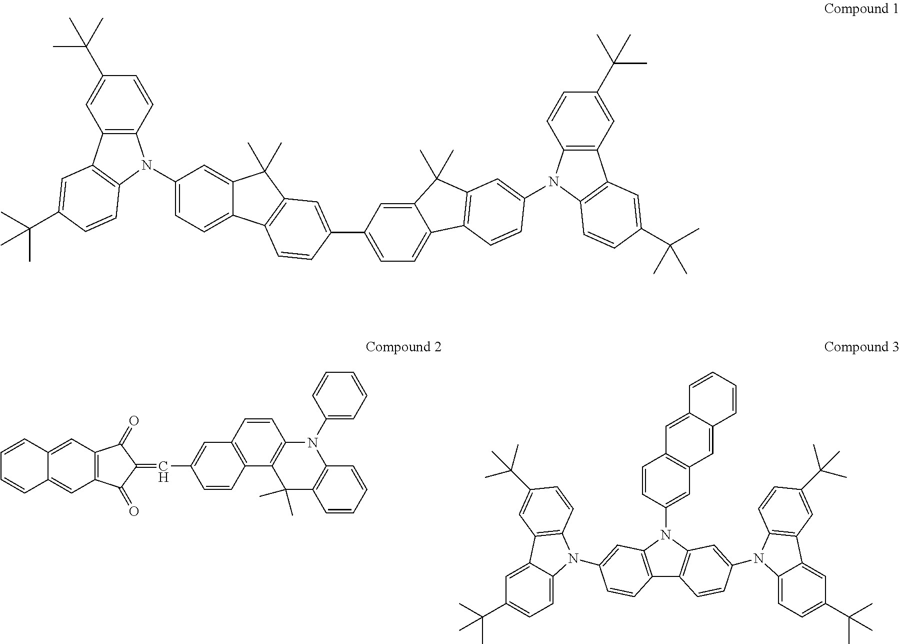

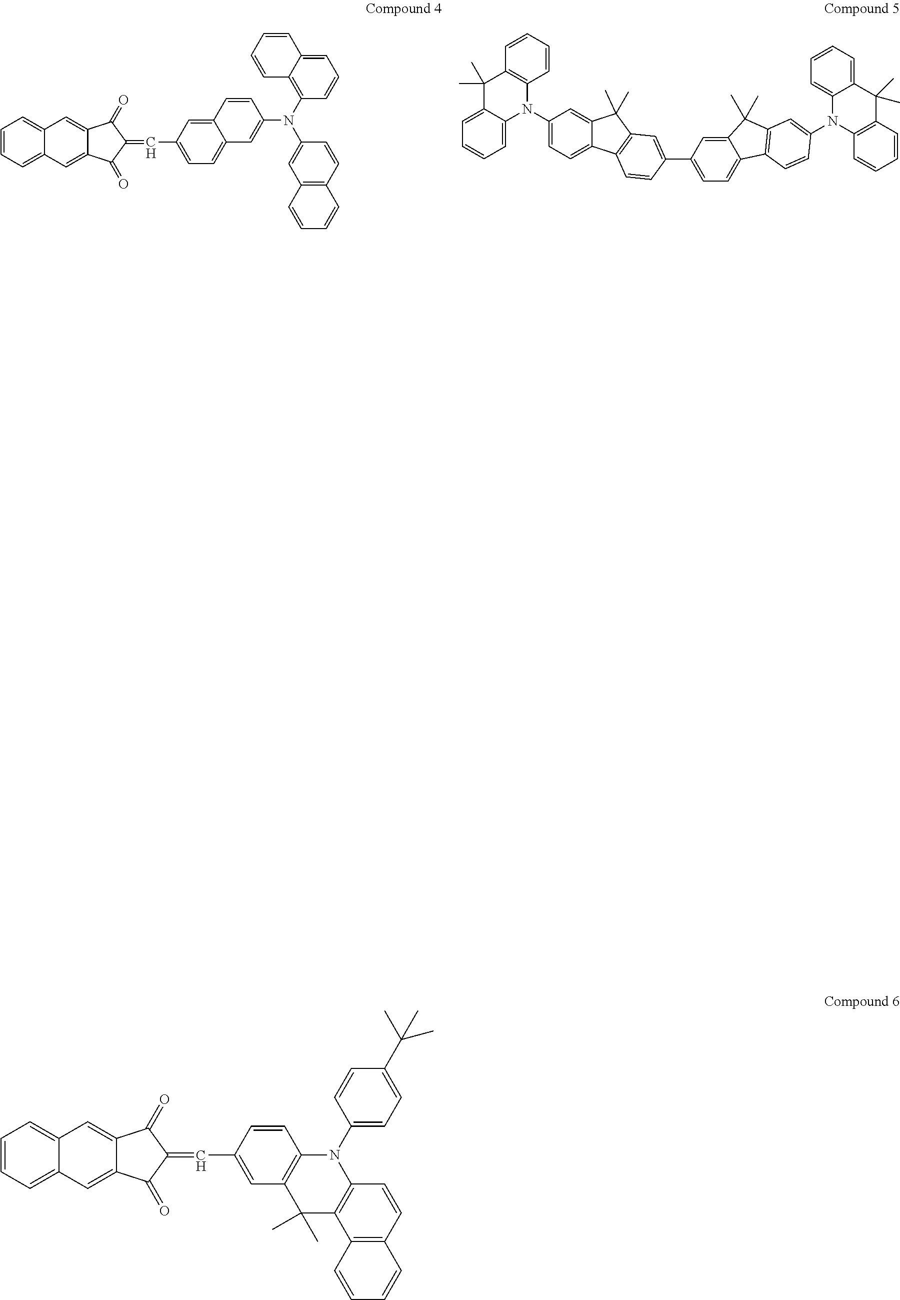

TABLE 3

| | | | | | Properties after a lapse of | |
|---|---|---|---|---|---|---|
| | Upper electrode | | Initial properties | | 1,000 h at 90° C. | |
| | Deposition | Stress | Relative | Dark current | Relative | Dark |
| | rate(Å/s) | (MPa) | sensitivity | (A/cm²) | sensitivity | current (A/cm²) |
| Example 1 | 1 | −312 | 100 | 1.60 × 10⁻¹⁰ | 100 | 1.55 × 10⁻¹⁰ |
| Example 2 | 2 | −196 | 100 | 1.57 × 10⁻¹⁰ | 100 | 1.52 × 10⁻¹⁰ |
| Example 3 | 4 | −63 | 100 | 1.34 × 10⁻¹⁰ | 100 | 1.28 × 10⁻¹⁰ |
| Example 4 | 0.6 | −437 | 100 | 1.72 × 10⁻¹⁰ | 100 | 1.71 × 10⁻¹⁰ |
| Example 5 | 1 | −312 | 100 | 1.55 × 10⁻¹⁰ | 100 | 1.52 × 10⁻¹⁰ |
| Example 6 | 4 | −63 | 100 | 1.48 × 10⁻¹⁰ | 100 | 1.41 × 10⁻¹⁰ |
| Example 7 | 1 | −312 | 100 | 1.63 × 10⁻¹⁰ | 100 | 1.62 × 10⁻¹⁰ |
| Example 8 | 0.6 | −437 | 100 | 1.58 × 10⁻¹⁰ | 100 | 1.54 × 10⁻¹⁰ |
| Comparative | 0.4 | −397 | 100 | 1.86 × 10⁻¹⁰ | 93 | 2.85 × 10⁻¹⁰ |
| example 1 | | | | | | |
| Comparative | 0.3 | −442 | 100 | 1.82 × 10⁻¹⁰ | 87 | 2.98 × 10⁻¹⁰ |
| example 2 | | | | | | |
| Comparative | 0.1 | −473 | 100 | 1.42 × 10⁻¹⁰ | 62 | 4.55 × 10⁻¹⁰ |
| example 3 | | | | | | |
| Comparative | 1.2 | −31 | 100 | 1.57 × 10⁻¹⁰ | — | — |
| example 4 | | | | | | |
| Comparative | 1.4 | −39 | 100 | 1.35 × 10⁻¹⁰ | — | — |
| example 5 | | | | | | |
| Comparative | 0.9 | −546 | 100 | 2.27 × 10⁻⁹ | 100 | 3.20 × 10⁻⁹ |
| example 6 | | | | | | |
| Comparative | 0.8 | −611 | 100 | 5.33 × 10⁻⁹ | 100 | 7.25 × 10⁻⁹ |
| example 7 | | | | | | |
| Comparative | 0.7 | −786 | 100 | 3.20 × 10⁻⁸ | 100 | 5.12 × 10⁻⁸ |
| example 8 | | | | | | |
| Comparative | 0.3 | −442 | 100 | 1.77 × 10⁻¹⁰ | 84 | 4.10 × 10⁻¹⁰ |
| example 9 | | | | | | |
| Comparative | 1.2 | −31 | 100 | 1.57 × 10⁻¹⁰ | — | — |
| example 10 | | | | | | |
| Comparative | 0.8 | −611 | 100 | 8.20 × 10⁻⁹ | 100 | 8.95 × 10⁻⁹ |
| example 11 | | | | | | |
| Comparative | 0.3 | −442 | 100 | 1.65 × 10⁻¹⁰ | 82 | 1.79 × 10⁻¹⁰ |
| example 12 | | | | | | |
| Comparative | 1.4 | −39 | 100 | 1.38 × 10⁻¹⁰ | — | — |
| example 13 | | | | | | |
| Comparative | 0.7 | −786 | 100 | 1.26 × 10⁻⁸ | 100 | 1.29 × 10⁻⁸ |
| example 14 | | | | | | |

In Examples 1 to 8, the deposition rate for forming the upper electrode was 0.5 Å/s or higher, and the stress of the upper electrode was within a range of −50 MPa to −500 MPa. Accordingly, a high SN ratio was obtained as an initial property, and properties thereof did not deteriorate even after the storage test was performed.

The initial properties of Comparative examples 1 to 3, 9, and 12 were equivalent to those of Examples 1 to 8. However, the photoelectric conversion efficiency of Comparative examples 1 to 3, 9, and 12 deteriorated after the storage test. Presumably, this is because the deposition rate for forming the upper electrode was lower than 0.5 Å/s, and thus, oxygen gas having been generated during the formation of ITO film by sputtering might be incorporated into the photoelectric conversion layer (organic film).

The initial properties of Comparative examples 4, 5, 10, and 13 were equivalent to those of Examples 1 to 8. However, the upper electrode of Comparative examples 4, 5, 10, and 13 were peeled from the photoelectric conversion layer (organic film) after the storage test. Presumably, this is because since the stress of the upper electrode was −50 MPa or more, adhesiveness between the photoelectric conversion layer (organic film) and the upper electrode might become insufficient, and the upper electrode might be peeled after the lapse of time. Since the peeling occurred, the photoelectric conversion efficiency and dark currents could not be measured in Comparative examples 4, 5, 10, and 13. Therefore, regarding Comparative examples 4, 5, 10, and 13, in Table 3, “−” is marked in the columns of the relative sensitivity (photoelectric conversion efficiency) and the level of dark currents measured after the storage test.

In Comparative examples 6 to 8, 11, and 14, the level of dark currents as an initial property was higher than in Examples 1 to 8, by a single digit or a higher degree. Presumably, this is because since the stress of the upper electrode was −500 MPa or less, the photoelectric conversion layer (organic film) might deform and become convex during the formation of the upper electrode film, whereby fine crack might be formed in this layer, and the upper electrode might intrude into the cracks. As a result, it is assumed that a high field intensity might be locally applied to the cracked portion, and electric charges might be injected into the photoelectric conversion layer from the cracks, whereby the level of dark currents might be heightened.

The above results shows that in a photoelectric conversion element constituted with a lower electrode, an electron blocking layer, a photoelectric conversion layer, a transparent upper electrode, and a sealing layer, if the upper electrode is formed of a transparent conductive oxide which is formed into a film at a deposition rate of 0.5 Å/s or higher by a sputtering method and has a stress of −50 MPa to −500 MPa, a photoelectric conversion element which has a high SN ratio and stays stable over a long period of time can be realized.

What is claimed is:

1. A method for producing a photoelectric conversion element comprising a lower electrode, an electron blocking layer, a photoelectric conversion layer, an upper electrode, and a sealing layer which are laminated on one another in this order, the method having the steps of:
preparing a substrate on which the lower electrode, the electron blocking layer and the photoelectric conversion layer are formed in this order; and
forming a transparent conductive oxide into a film at a deposition rate of 0.5 Å/s or higher by a sputtering method to form the upper electrode having a stress of −50 MPa to −500 MPa on the photoelectric conversion layer.

2. The method for producing a photoelectric conversion element according to claim 1,
wherein the photoelectric conversion layer has a bulk heterostructure in which an n-type organic semiconductor material is mixed with a p-type organic semiconductor material.

3. The method for producing a photoelectric conversion element according to claim 2,
wherein the n-type organic semiconductor material is a fullerene or a fullerene derivative.

4. The method for producing a photoelectric conversion element according to claim 1,
wherein the upper electrode has a thickness of 5 nm to 20 nm.

5. The method for producing a photoelectric conversion element according to claim 1,
wherein the upper electrode is formed at a deposition rate of 10 Å/s or lower.

6. The method for producing a photoelectric conversion element according to claim 2,
wherein the p-type organic semiconductor material contains a compound represented by General formula (1), 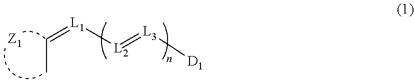
wherein Z₁ is a ring which contains at least two carbon atoms, and represents a 5-membered ring, a 6-membered ring, or a condensed ring which contains at least one of 5-membered ring and 6-membered ring; each of L₁, L₂, and L₃ independently represents unsubstituted methine groups or substituted methine groups; D₁ represents an atomic group; and n represents an integer of 0 or greater.

7. A method for producing an imaging device having a photoelectric conversion element, the method having a step of producing the photoelectric conversion element by the method for producing a photoelectric conversion element according to claim 1.
